(19) United States
(12) Patent Application Publication
(10) Pub. No.: US 2011/0117744 A1
(43) Pub. Date: May 19, 2011

(54) PATTERN FORMING METHOD AND PATTERN FORMING APPARATUS

(76) Inventor: Shinichi ITO, Kanagawa (JP)

(21) Appl. No.: 12/949,409

(22) Filed: Nov. 18, 2010

(30) Foreign Application Priority Data
Nov. 19, 2009 (JP) 2009-264273
Sep. 14, 2010 (JP) 2010-206126

(51) Int. Cl. H01L 21/311; B05C 13/00; B29C 59/02

(52) U.S. Cl. 438/702; 118/56; 425/90; 257/E21.257

(57) ABSTRACT

According to one embodiment, a first pattern is formed at first pattern coverage in a first region on a film to be processed and a second pattern is formed at second pattern coverage in a second region on the film to be processed. During the formation of the second pattern, a second film formed of a block copolymer containing film or the like is formed on the film to be processed and is self-assembled. A plurality of kinds of polymers contained in the self-assembled second film are selectively removed to leave at least one kind of polymer to form the second pattern to bring the second coverage close to the first pattern coverage.

### CROSS-REFERENCE TO RELATED APPLICATIONS

This application is based upon and claims the benefit of priority from the prior Japanese Patent Application No. 2009-264273, filed on Nov. 19, 2009 and 2010-206126, filed on Sep. 14, 2010; the entire contents of all of which are incorporated herein by reference.

### FIELD

Embodiments described herein relate generally to a pattern forming method and a pattern forming apparatus.

### BACKGROUND

In formation of a circuit pattern in a semiconductor process, during circuit pattern exposure at a peripheral edge of a substrate to be processed, a part of an exposure region extends to an edge-cut region of a resist or the outside of the substrate. Therefore, a part of a chip region is lost and a region not functioning as a product (a non-product region) is formed. These regions are unnecessary regions in product manufacturing. From a viewpoint of improvement of throughput of an exposure process, it is desirable not to expose the regions. However, it is known that, when a region not including a pattern (a non-exposure region) is present in the peripheral edge of the substrate to be processed, a product region near the region is affected by fluctuation in an etching rate due to a pattern coverage difference, fluctuation in a processing shape, or deterioration in flatness in a CMP process performed after the processing. A peripheral edge exposure method is proposed to overcome this problem.

For example, Japanese Patent Application Laid-Open No. 2008-210877 and Japanese Patent Application Laid-Open No. 2009-141263 disclose methods of separately applying exposure for adjusting coverage (peripheral edge coverage adjustment exposure) to a product mask non-exposure region of a peripheral edge. Japanese Patent Application Laid-Open No. 2008-210877 discloses a method of exposing a peripheral edge of a wafer in a mask-less manner. The method includes controlling shape, size, and coverage of light emitted from a light source on the wafer and performing the peripheral edge coverage adjustment exposure while rotating the wafer. Japanese Patent Application Laid-Open No. 2009-141263 discloses a method of controlling, using, separately from a photomask for product, a photomask on which a region having a plurality of pattern densities is formed, an exposure region of the photomask to obtain desired pattern density and performing the peripheral edge coverage adjustment exposure according to a shot position.

Japanese Patent Application Laid-Open No. H11-162833 discloses a method of determining a coordinate of a region to be subjected to the peripheral edge coverage adjustment exposure. The method includes measuring a coordinate value of a peripheral edge with an external shape detector, calculating, based on the coordinate value of the peripheral edge, a coordinate value (an orthogonal coordinate or an angular coordinate) of a substrate, and exposing an exposure region a predetermined distance apart from a center coordinate value of the substrate in a radial direction. As disclosed in these patent documents, the peripheral edge coverage adjustment exposure is applied to the product mask non-exposure region of the peripheral edge by another kind of exposure.

When the peripheral edge coverage adjustment exposure is performed separately from the product mask exposure, it is possible to prevent the influence on the product region due to the non-exposure region. However, because the number of times of exposure increases, occupied time of an exposing machine per one substrate to be processed is extended and productivity is deteriorated.

### BRIEF DESCRIPTION OF THE DRAWINGS

FIG. 1 is a schematic plan view of a substrate to be processed that is a target of formation of Via plugs in a first embodiment;

FIGS. 2A to 2H are schematic sectional views of a pattern forming process in a Via plug forming method according to the first embodiment;

FIG. 3 is a flowchart of a flow of a pattern forming process in the Via plug forming method according to the first embodiment;

FIG. 4 is a schematic diagram of an example of a block copolymer (BCP) film used in a second film in the first embodiment;

FIG. 5 is a characteristic chart of an example of a relation between χN with respect to a weight fraction of one block polymer of the diblock copolymer and a structure obtained by self-assembled the polymer mixture;

FIG. 6 is a schematic diagram of an example of the structure of the self-assembled block copolymer film;

FIG. 7 is a plan view of a state in which the substrate to be processed is exposed with a circuit processing pattern by a method of manufacturing a semiconductor device in the past;

FIG. 8 is a plan view of a state in which exposure of the circuit processing pattern is performed by the method of manufacturing a semiconductor device in the past in a product region and a non-product region of the substrate to be processed;

FIGS. 9A to 9J are schematic sectional views of a pattern forming process in a wire forming method according to a second embodiment;

FIG. 10 is a flowchart for explaining a flow of the pattern forming process in the wire forming method according to the second embodiment;

FIGS. 11A to 11I are schematic sectional views of a pattern forming process in a Via plug forming method according to a third embodiment;

FIG. 12 is a flowchart for explaining a flow of the pattern forming process in the Via plug method according to the third embodiment;

FIGS. 13A to 13H are schematic sectional views of a pattern forming process in a Via plug forming method according to a fourth embodiment;

FIG. 14 is a flowchart for explaining a flow of the pattern forming process in the Via plug forming method according to the fourth embodiment;

FIG. 15 is a schematic diagram of an example of a polymer mixed film used for a second film in the fourth embodiment;

FIGS. 16A to 16J are schematic sectional views of a pattern forming process in a wire forming method according to a fifth embodiment;

FIG. 17 is a flowchart for explaining a flow of the pattern forming process in the wire forming method according to the fifth embodiment;

FIGS. 18A to 18I are schematic sectional views of a pattern forming process in a Via plug forming method according to a sixth embodiment;

FIG. 19 is a flowchart for explaining a flow of the pattern forming process in the Via plug method according to the sixth embodiment;

FIGS. 20A to 20K are schematic sectional views of a pattern forming process in a wire forming method in a seventh embodiment;

FIG. 21 is a flowchart for explaining a flow of the pattern forming process in the wire forming method according to the seventh embodiment;

FIGS. 22A to 22I are schematic sectional views of a pattern forming process in a wire forming method according to an eighth embodiment;

FIG. 23 is a flowchart for explaining a flow of the pattern forming process in the wire forming method according to the eighth embodiment;

FIGS. 24A to 24I are schematic sectional views of a pattern forming process in a Via plug forming method according to a ninth embodiment;

FIG. 25 is a flowchart for explaining a flow of the pattern forming process in the Via plug method according to the ninth embodiment;

FIG. 26 is a diagram of a schematic configuration of a pattern forming apparatus according to a tenth embodiment;

FIGS. 27A to 27D are schematic sectional views of a method of applying a block copolymer material by the pattern forming apparatus according to the tenth embodiment;

FIGS. 28A to 28D are schematic sectional views of another method of applying the block copolymer material by the pattern forming apparatus according to the tenth embodiment;

FIG. 29 is a schematic diagram of an example of a state of supply of the block copolymer material by the pattern forming apparatus according to the tenth embodiment on a substrate to be processed;

FIG. 30 is a schematic diagram of an example of a state of supply of the block copolymer material by the pattern forming apparatus according to the tenth embodiment on the substrate to be processed;

FIG. 31 is a schematic sectional view of another example of a method of supplying the block copolymer material by the pattern forming apparatus according to the tenth embodiment on the substrate to be processed;

FIG. 32 is a diagram of a schematic configuration of the pattern forming apparatus according to the tenth embodiment;

FIGS. 33A and 33B are schematic sectional views of imprint processing by the pattern forming apparatus according to the tenth embodiment; and

FIG. 34 is a diagram of an example of a module system according to the tenth embodiment.

### DETAILED DESCRIPTION

In general, according to one embodiment, a first film is formed in a first region on a film to be processed formed on a substrate to be processed and the first film is patterned, whereby a first pattern having first pattern coverage as pattern coverage is formed. Subsequently, a second pattern having second pattern coverage as pattern coverage is formed in a second region on the film to be processed different from the first region. When the second pattern is formed, a second film formed of a block copolymer containing film or a polymer mixed film is formed on the film to be processed and the second film is self-assembled. A plurality of kinds of polymers contained in the self-assembled second film are selectively removed to leave at least one kind of polymer, whereby the second pattern is formed in the second region to bring the second pattern coverage close to the first pattern coverage.

Exemplary embodiments of a pattern forming method and a pattern forming apparatus will be explained below in detail with reference to the accompanying drawings. The present invention is not limited to the following embodiments. For ease of understanding, in some case, scales of members are different from actual scales. The same holds true among the drawings.

### First Embodiment

In the first embodiment, a method of manufacturing a semiconductor device using directed self-assembly (DSA), which is an embodiment concerning Via plug formation for a lower layer wire formed on a wafer for semiconductor manufacturing, is explained. In this embodiment, a block copolymer (BCP) formed by polymethyl methacrylate (PMMA) and polystyrene (PS) is selectively applied to a non-product region in a semiconductor substrate. A processing error in an etching process for a product region can be reduced by self-assembled the block copolymer and selectively removing a PMMA section. A pattern forming method that can adjust pattern coverage of the non-product region to be substantially the same as circuit pattern coverage is explained below.

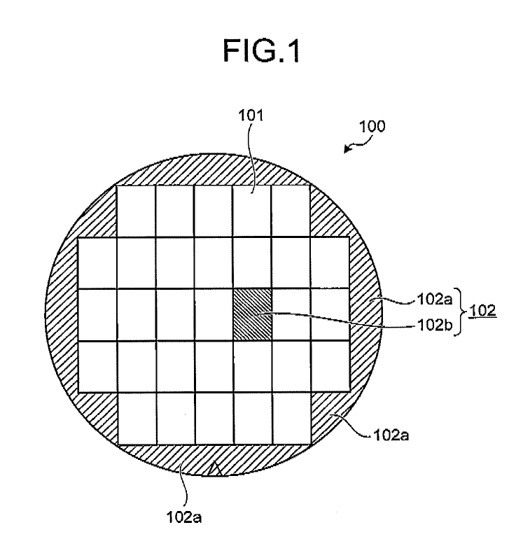

FIG. 1 is a schematic plan view of a substrate to be processed 100 that is a target of formation of Via plugs. Although FIG. 1 is a plan view, hatching is applied to the figure for ease of understanding. Rectangular regions surrounded by thick lines in FIG. 1 indicate product regions 101 where products (devices) are respectively formed. The substrate to be processed 100 includes non-product regions 102. The non-product regions 102 include a peripheral edge region (a substrate peripheral edge region) 102a of the substrate to be processed 100 where a product (a device) is not formed and a defective region 102b that is originally the product region 101 but does not function as a product (a device) because of occurrence of a defect before a Via plug forming process. The defective region 102b includes a region where an operation failure of a product (a device) could occur because of, for example, wire short-circuit, wire open, or current leak. In the following explanation, the non-product region 102 is the substrate peripheral edge region 102a. It is assumed that Via plugs are formed only in the product regions 101 without being formed in the non-product region 102.

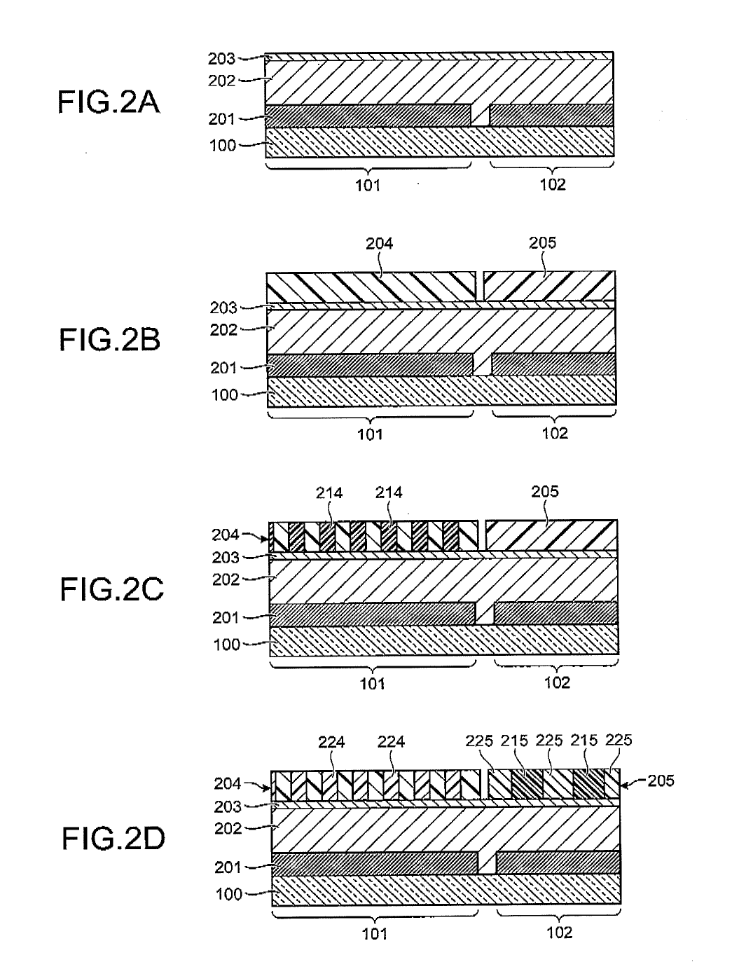

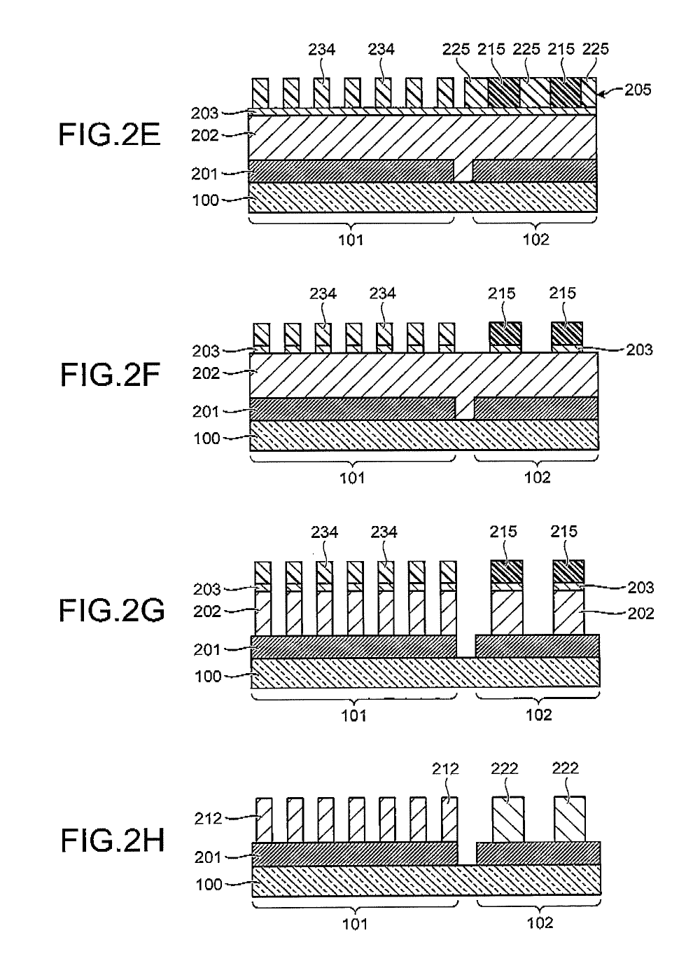

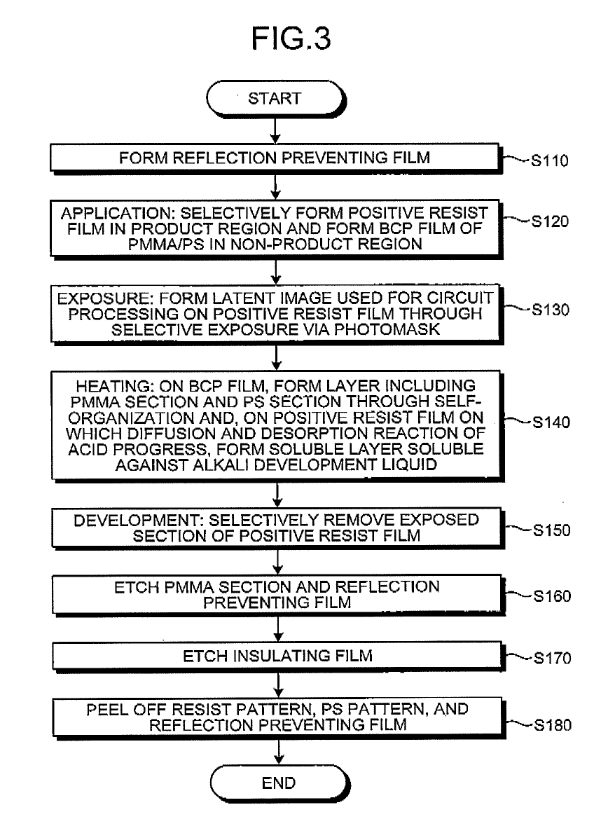

FIGS. 2A to 2H are schematic sectional views of a pattern forming processing in a Via plug forming method according to the first embodiment. FIG. 3 is a flowchart for explaining a flow of the pattern forming process in the Via plug forming method according to the first embodiment.

First, the substrate to be processed 100 having a lower layer wire 201 provided on one surface and a silicon oxide film formed on the lower layer wire 201 as an insulating film 202, which is a film to be processed, is prepared. A antireflection film 203 is formed on the insulating film 202 of the substrate to be processed 100 by rotational application (step S110 in FIG. 2A). A first film 204 and a second film 205 are separately applied to the product region 101 and the non-product region 102 on the antireflection film 203 by a selective application method (step S120 in FIG. 2B). In other words, the first film 204 is selectively applied to the product region 101 and the second film 205 is selectively applied to the non-product region 102. The selective film formation is, for example, performed for the first film 204 by an application method by ink-jet and performed for the second film 205 by squeeze processing for further spreading an applied film formed by inkjet, for example, with a spatula.

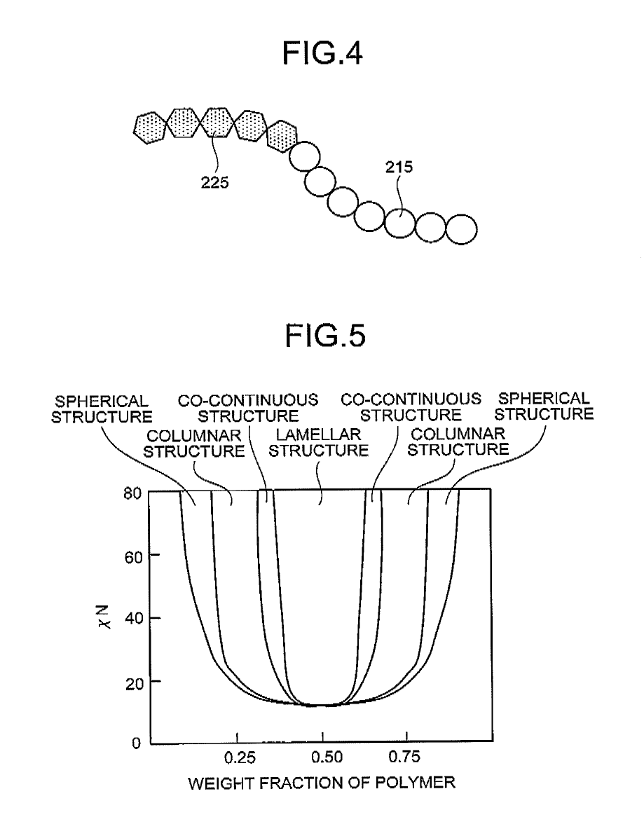

A photosensitive material film is used for the first film 204. In this embodiment, a positive chemically amplified resist film is used as the photosensitive material film. A block copolymer (BCP) film is used for the second film 205. FIG. 4 is a schematic diagram of an example of the block copolymer (BCP) film used for the second film 205. In this embodiment, as the block copolymer film, a block copolymer film including polystyrene (PS) sections 215 and polymethyl methacrylate (PMMA) sections 225 as shown in FIG. 4 is used.

A ratio of each block polymer of the block copolymer (BCP) film can be adjusted according to coverage of a pattern in the product region 101. Compositions of the block copolymers are determined such that a weight fraction of the block polymers to be removed after self-assembly is larger as the coverage of the pattern in the product region 101 is smaller. Further, compositions of the block copolymers are determined such that a weight fraction of the block polymers to be removed after self-assembly is smaller as the coverage of the pattern in the product region 101 is larger.

For example, when the coverage of the pattern in the product region 101 is about 80%, a block copolymer in which a weight fraction of polystyrene (PS) is set to 0.80 same as the coverage in the product region 101 is used. FIG. 5 is a characteristic chart of an example of a relation between χN with respect to a weight fraction of one block polymer in diblock copolymer and a structure obtained by self-assembled the diblock copolymer. χ represents repulsion between two kinds of polymers forming the copolymer and N represents a degree of polymerization of the monomer. The structure of the self-assembled diblock copolymer can be formed as different structures such as spherical structure, columnar structure, co-continuous structure, and lamellar structure as shown in FIG. 5 by adjusting a combination of the weight fraction of one block polymer and χN.

The self-assembled structure obtained from the block copolymers can be controlled by adjusting self-assembled temperature and pressure. For example, in the case of a block copolymer film formed by polymethyl methacrylate (PMMA) and polystyrene (PS), a coverage adjusted pattern can be formed as self-assembled structure in which polystyrene (PS) surrounds columnar polymethyl methacrylate (PMMA) by adjusting the self-assembled temperature.

Subsequently, an exposure step for forming a latent image on the first film 204 is performed. The formation of the latent image is performed by transferring latent images 214 used for circuit processing onto the first film 204 by selective exposure on the first film 204 via a photomask (step S130 in FIG. 2C).

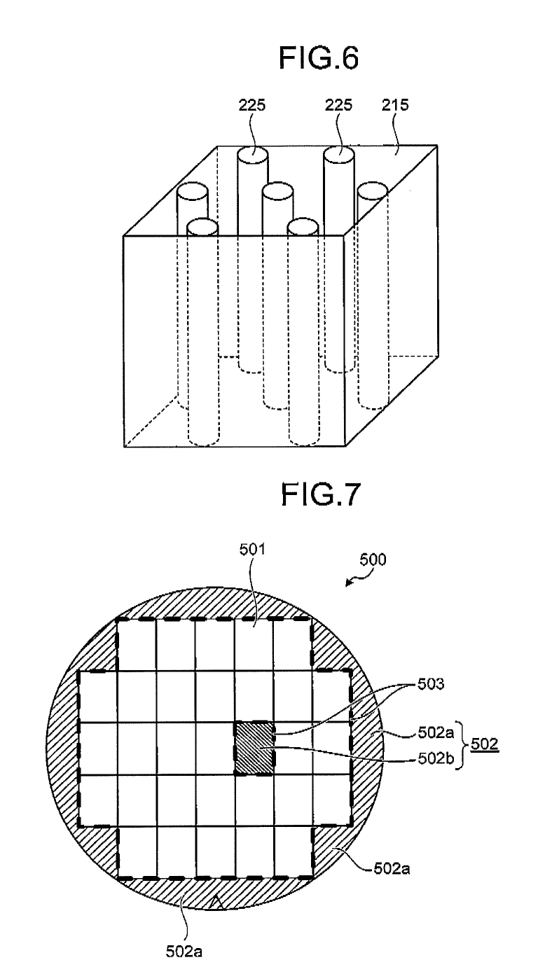

A heating step for heating the substrate to be processed 100 is performed. Diffusion and reaction of acid progress at the latent images in the first film 214 according to the heating step. Soluble layers 224 soluble against development liquid are formed in exposure regions, i.e., regions where the latent images 214 are formed. Self-assembly of the block copolymer film progresses in the second film 205 according to the heating step and the block copolymer film is divided into the polystyrene (PS) sections 215 and the polymethyl methacrylate (PMMA) sections 225 (step S140 in FIG. 2D). As shown in FIG. 6, a structure in which the polymethyl methacrylate (PMMA) sections 225 change to columnar structures upright with respect to an in-plane direction of the substrate to be processed 100 and the polystyrene (PS) sections 215 are upright with respect to the in-plane direction of the substrate to be processed 100 to surround the columnar structures is formed. FIG. 6 is a schematic diagram of an example of the self-assembled structure of the block copolymer film.

A developing step is performed by using the development liquid. The second film 205 is insoluble in the development liquid. Because the first film 204 is a positive resist film, exposure sections (the soluble layers 224) are selectively resolved in the development liquid and positive resist patterns 234 are formed as patterns for circuit processing (step S150 in FIG. 2E).

Anisotropic etching of the polymethyl methacrylate (PMMA) sections 225 and its underlying antireflection film 203 is performed. The etching is performed by reactive ion etching (RIE) by using fluorocarbon gas and oxygen gas. In the product region 101, the exposed antireflection film 203 is etched and removed. In the non-product region 102, the polymethyl methacrylate (PMMA) sections 225 of the second film 205 are selectively etched and the remaining polystyrene (PS) sections 215 are formed as patterns. The exposed antireflection film 203 is etched and removed with the patterns of the polystyrene (PS) sections 215 as masks (step S160 in FIG. 2F).

Anisotropic etching of the insulating film 202 is performed. The etching is performed by the RIE using fluorocarbon gas (step S170 in FIG. 2G).

The positive resist patterns 234 used as the masks for circuit processing and the polystyrene (PS) sections 215 are removed by ashing and the antireflection film 203 is removed to form patterns of the insulating film 202 (step S180 in FIG. 2H). As the patterns of the insulating film 202, insulating film patterns 212 formed in the product region 101 and insulating film patterns 222 formed in the non-product region 102 are formed. Thereafter, after barrier metal films are formed on the surfaces of the patterns of the insulating film 202, barrier metal at the bottom is removed, metal is buried on the bottom, and a film of the metal formed outside a Via region is abraded and removed by the CMP, whereby patterns functioning as Via plugs can be formed.

As explained above, in the first embodiment, regardless of the fact that the exposure for processing pattern formation is applied to only the first film 204, the insulating film 202 can be processed at high accuracy for both the shape of a processed pattern and a processing dimension.

When no pattern is present in the non-product region 102, an excessively large amount of etchant is supplied from the non-product region 102 at a peripheral edge of the product region 101 during processing of the insulating film 202. Therefore, etching speed increases and processing non-uniformity occurs between the peripheral edge of the product region 101 and the product region 101 on the inner side of the substrate to be processed 100 (the product region 101 not adjacent to the non-product region 102).

FIG. 7 is a plan view of a state in which a circuit processing pattern is exposed on a substrate to be processed 500 by a method of manufacturing a semiconductor device in the past. Although FIG. 7 is a plan view, hatching is applied to the figure for ease of understanding. A rectangular region in FIG. 7 indicates one exposure region and includes a product region 501 where a product (a device) is formed. A peripheral edge region (a substrate peripheral edge region) 502a where exposure is not performed is present in a peripheral edge section of the substrate to be processed 500. On the substrate to be processed 500, there is a defective region 502b that is originally the product region 501 but does not function as a product (a device) because a defect occurs before a circuit processing pattern forming process. It is assumed that circuit processing pattern exposure for non-product regions 502 (the substrate peripheral edge region 502a and the defective region 502b) is not performed.

When etching is applied to the substrate to be processed 500 on which the circuit processing pattern is exposed in this way, consumed amounts of etching gas are substantially different near boundaries 503 between the product region 501 where exposure is performed and the non-product regions 502 where exposure is not performed. Non-reacting gas and etchant are present in the boundary sections. Therefore, etching speed in this region increase and a dimension difference involved in the increase in the etching speed occurs. In the CMP after the via material formation, a difference in an abrasion rate occurs in the boundary sections and processing abnormality such as remaining of the Via material in an unnecessary place occurs.

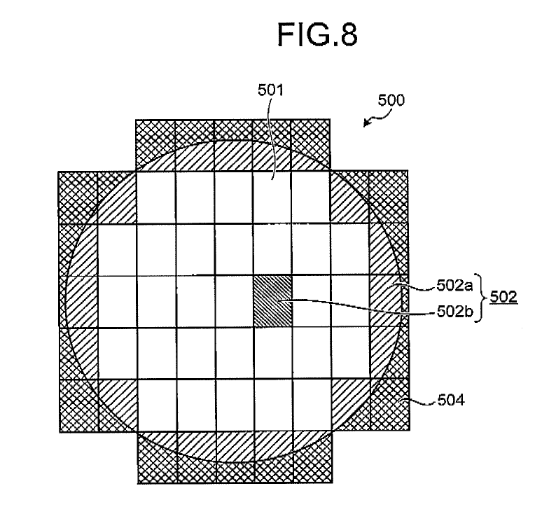

FIG. 8 is a plan view of a state in which exposure of the circuit processing pattern is applied to the product region 501 and the non-product region 502 of the substrate to be processed 500 by the method of manufacturing a semiconductor device in the past. Although FIG. 8 is a plan view, hatching is applied to the figure for ease of understanding. In this case, in the substrate to be processed 500, no difference occurs in environments adjacent to all exposure regions (product regions 501). However, a chipped shot region 504 at the peripheral edge of the substrate where, even if exposure is performed and a circuit is formed, the circuit does not function as a product and the substrate peripheral edge region 502a and the defective region 502b for which exposure is originally unnecessary are exposed. Therefore, occupied time of an exposing machine per one substrate to be processed is extended and productivity is deteriorated. When the peripheral edge exposure method is adopted, exposure is performed a plurality of number of times and a process is complicated. Further, an exposing apparatus for peripheral edge exposure is necessary.

Effects of this embodiment are explained with reference to FIG. 7. In this embodiment, regardless of the fact that the exposure for processing pattern formation is applied to only the first film 204, the patterns of the polystyrene (PS) sections 215 can be formed in the non-product region 502 by using the self-assembly of the block copolymer. Consequently, at a processing stage of the insulating film 202, processing of the insulating film 202 is performed in the non-product region 502 with the patterns of the polystyrene (PS) sections 215 as masks. Therefore, in the product region 501 positioned near the boundary 503 between the product region 501 and the non-product region 502, an appropriate amount of etcharit is supplied and consumed as in the product region 501 on the inner side of the substrate to be processed 100 (the product region 501 not adjacent to the non-product region 502). Therefore, the insulating film 202 can be processed at high accuracy for both the shape of a processed pattern and a processing dimension.

In the first embodiment, patterning using self-assembly of the block copolymer is applied to the substrate peripheral edge region 502a, so that usage of the exposing apparatus can be reduced compared with usage of the exposing apparatus that performs peripheral exposure as in the past and productivity and cost of the exposing apparatus can be improved.

In the explanation of this embodiment, the positive chemically amplified resist is used as the first film 204. However, a negative chemically amplified resist can also be used. A resist that does not have an amplification action and causes selective solubility with respect to development liquid through simple photodecomposition or an optical crosslinking reaction can also be used.

In the above explanation, the non-product region 102 is the substrate peripheral edge region 102a. However, when there is the defective region 102b, a pattern can be formed in the defective region 102b by the same method. In this case, exposure is applied to only the product region 101, which is the circuit processing region, usage of the exposing apparatus can be reduced compared with usage of the exposing apparatus that performs peripheral exposure as in the past and productivity and cost of the exposing apparatus can be improved.

As a modification of this embodiment, after selective application of a resist film and exposure and development of a pattern for circuit processing are applied to the product region 101, selective application and self-assembly of a block copolymer film can be applied to the non-product region 102. As another modification of this embodiment, after selective application and self-assembly of the block copolymer film are applied to the non-product region 102, selective application of a resist film and exposure and development of a pattern for circuit processing can be applied to the product region 101. In this embodiment, the wafer for semiconductor manufacturing is the substrate to be processed 100. However, various applications are possible as long as the applications are for the same pattern processing for, for example, in processing of mask blanks, performing processing of a light blocking film and a substrate using, as a mask, a pattern self-assembled by selectively applying a resist to a pattern area and selectively applying a block copolymer in a peripheral edge of the pattern area.

According to the first embodiment, it is possible to efficiently form a pattern for circuit processing and perform circuit processing at high accuracy for both the shape of a processing pattern and a processing dimension using the pattern for circuit processing.

### Second Embodiment

In the second embodiment, a method of manufacturing a semiconductor device using DSA, which is an embodiment concerning wire formation for a lower layer wire, is explained. In this embodiment, as in the first embodiment, a block copolymer (BCP) formed by polymethyl methacrylate (PMMA) and polystyrene (PS) is selectively applied to a non-product region in a semiconductor substrate. A processing error in an etching process for a product region can be reduced by self-assembled the block copolymer and selectively removing a PMMA section. A pattern forming method that can adjust pattern coverage of the non-product region to be substantially the same as circuit pattern coverage without using exposure is explained below.

In the second embodiment, wires are formed on the substrate to be processed 100 shown in FIG. 1. It is assumed that wires are formed only in the product region 101 without being formed in the non-product region 102. The non-product region 102 includes the peripheral edge region (the substrate peripheral edge region) 102a of the substrate to be processed 100 where a product (a device) is not formed and the defective region 102b that is originally the product region 101 but does not function as a product (a device) because of occurrence of a defect before a wire forming process. In the following explanation, the non-product region 102 is the substrate peripheral edge region 102a.

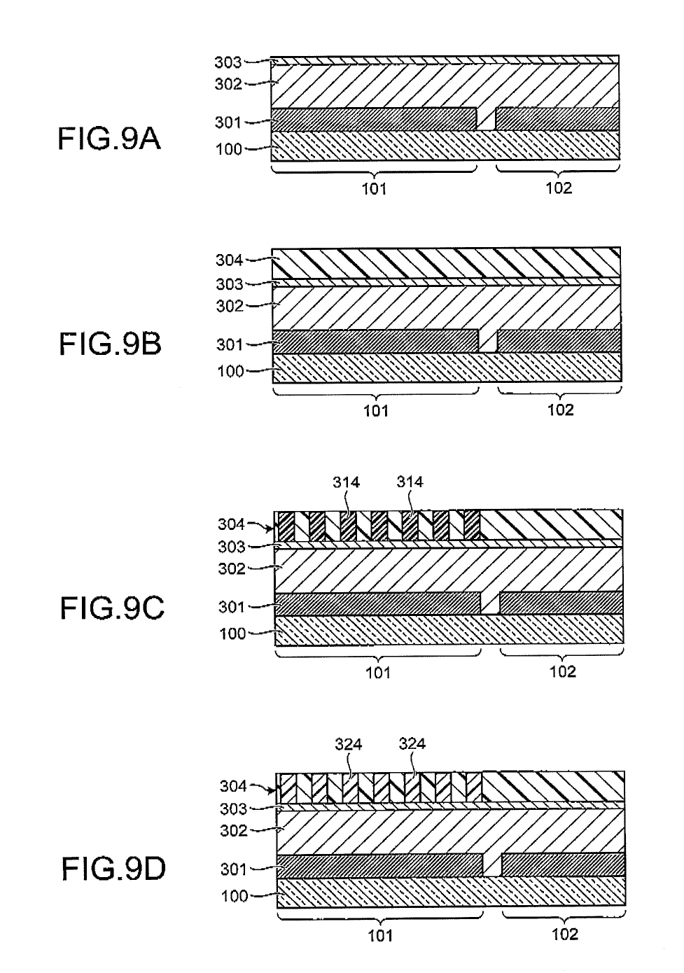

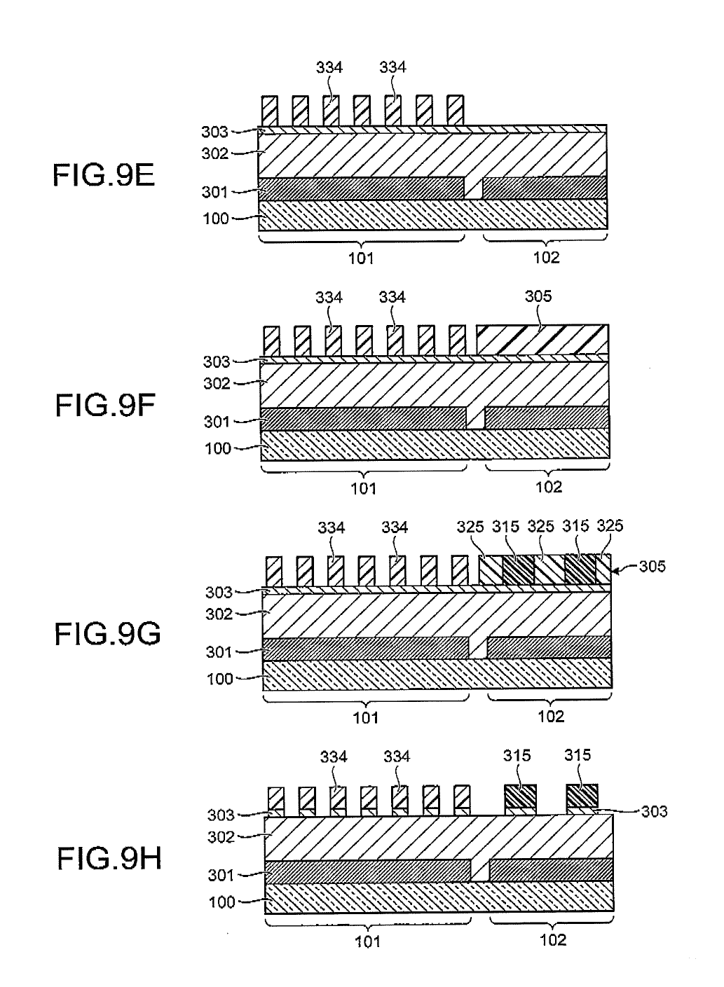

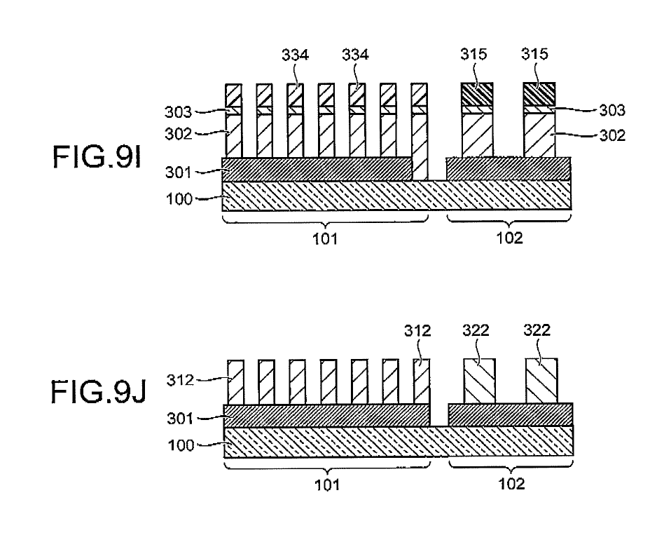

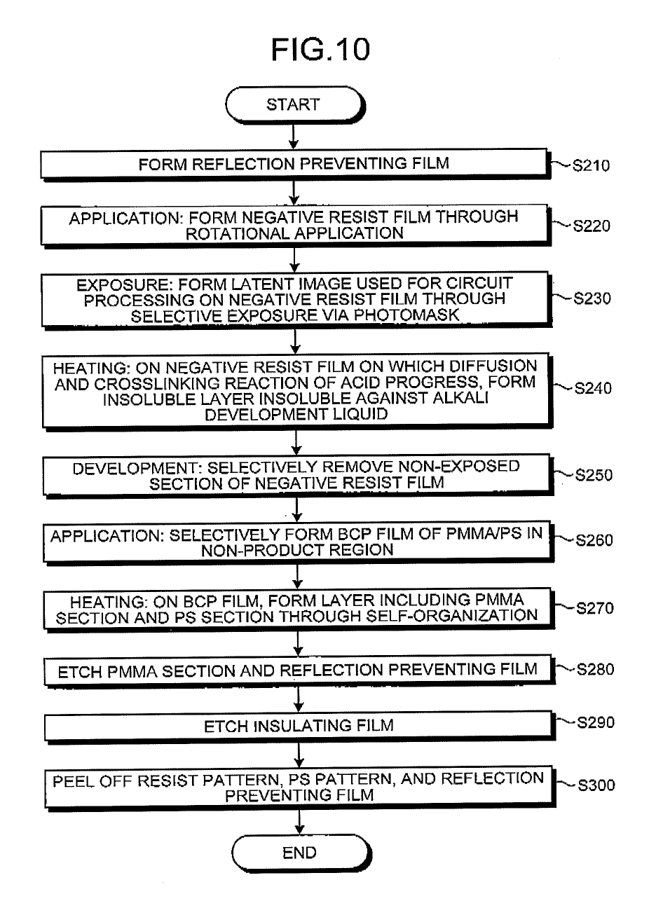

FIGS. 9A to 9J are schematic sectional views of a pattern forming process in a wire forming method according to the second embodiment. FIG. 10 is a flowchart for explaining a flow of the pattern forming process in the wire forming method according to the second embodiment.

First, the substrate to be processed 100 having a lower layer wire 301 provided on one surface and a silicon oxide film formed on the lower layer wire 301 as an insulating film 302, which is a film to be processed, is prepared. A antireflection film 303 is formed on the insulating film 302 of the substrate to be processed 100 by rotational application (step S210 in FIG. 9A). A first film 304 is applied on the antireflection film 303 by a rotational application method (step S220 in FIG. 9B). A photosensitive material film is used for the first film 304. In this embodiment, a negative chemically amplified resist film is used as the photosensitive material film.

Subsequently, an exposing step for forming a latent image in the product region 101 of the first film 304 is performed. The formation of the latent image is performed by transferring latent images 314 used for circuit processing onto the first film 304 by selective exposure for the first film 304 via a photomask (step S230 in FIG. 9C). A latent image is not formed on the first film 304 on the non-product region 102.

A heating step for heating the substrate to be processed 100 is performed. Diffusion and crosslinking reaction of acid progress at the latent images in the first film 314 according to the heating process and insoluble layers 324 insoluble against alkali development liquid are formed in exposure regions, i.e., regions where the latent images 314 are formed (step S240 in FIG. 9D).

A developing step is performed by using the development liquid. Because the first film 304 is a negative resist film, a region other than exposure sections (the insoluble layers 324) is selectively resolved in the development liquid and resist patterns 334 are formed as patterns for circuit processing (step S250 in FIG. 9E). The resist film in the non-product region 102 where latent image formation is not performed is also removed by the development liquid.

A self-assembled pattern is formed in the non-product region 102 by using a block copolymer. First, a second film 305 is applied on the antireflection film 303 in the non-product region 102, where the first film 304 is removed, by a selective application method and dried (step S260 in FIG. 9F). A block copolymer (BCP) film is used for the second film 305. In this embodiment, a block copolymer film including polystyrene (PS) sections 315 and polymethyl methacrylate (PMMA) sections 325 is used as the block copolymer film. The selective film formation is performed by squeeze processing for spreading an applied film with a spatula.

A ratio of each block polymer of the block copolymer (BCP) film can be adjusted according to coverage of a pattern in the product region 101. Compositions of the block copolymers are determined such that a weight fraction of the block polymers to be removed after self-assembly is larger as the coverage of the pattern in the product region 101 is smaller. Further, compositions of the block copolymers are determined such that a weight fraction of the block polymers to be removed after self-assembly is smaller as the coverage of the pattern in the product region 101 is larger.

For example, when the coverage of the pattern in the product region 101 is about 50%, a block copolymer in which a weight fraction of polystyrene (PS) is set to 0.50 same as the coverage in the product region 101 is used. A self-assembled structure obtained from the block copolymers can be controlled by adjusting self-assembly temperature. For example, in the case of a diblock copolymer film formed by polymethyl methacrylate (PMMA) and polystyrene (PS), the diblock copolymer film can be formed as a lamellar structure of vertical orientation by adjusting self-assembly temperature.

Subsequently, at least the substrate peripheral edge region 102a is heated to advance self-assembly in the second film 305. Consequently, the block copolymer film is divided into the polystyrene (PS) sections 315 and the polymethyl methacrylate (PMMA) sections 325 and a lamellar structure in which the polystyrene (PS) sections 315 and the polymethyl methacrylate (PMMA) sections 325 are upright with respect to the in-plane direction of the substrate to be processed 100 is formed (step S270 in FIG. 9G).

Anisotropic etching of the polymethyl methacrylate (PMMA) sections 325 and its underlying antireflection film 303 is performed. The etching is performed by the RIE by using fluorocarbon gas and oxygen gas. In the product region 101, the exposed antireflection film 303 is etched and removed. In the non-product region 102, the polymethyl methacrylate (PMMA) sections 325 of the second film 305 are selectively etched and the remaining polystyrene (PS) sections 315 are formed as patterns. The exposed antireflection film 303 is etched and removed with the patterns of the polystyrene (PS) sections 315 as masks (step S280 in FIG. 9H).

Anisotropic etching of the insulating film 302 is performed. The etching is performed by the RIE using fluorocarbon gas (step S290 in FIG. 9I).

The resist patterns 334 used as the masks for circuit processing and the polystyrene (PS) sections 315 are removed by aching and the antireflection film 303 is removed to form patterns of the insulating film 302 (step S300 in FIG. 9J). As the patterns of the insulating film 302, insulating film patterns 312 formed in the product region 101 and insulating film patterns 322 formed in the non-product region 102 are formed. Thereafter, after barrier metal films are formed on the surfaces of the patterns of the insulating film 312, barrier metal at the bottom is removed, metal is buried on the bottom, and a wire material formed on the outside of a wire region is abraded and removed by the CMP, whereby patterns functioning as wires can be formed.

As explained above, in the second embodiment, regardless of the fact that the exposure for processing pattern formation is applied to only the first film 304 on the product region 101, the insulating film 302 can be processed at high accuracy for both the shape of a processed pattern and a processing dimension.

Influence in the case where this embodiment is not applied is explained with reference to FIG. 8. When no pattern is present in the non-production region 502, an excessively large amount of etchant is supplied from the outside of the product region 501 in the product region 501 positioned near the boundary 503 between the product region 501 and the non-product region during processing of the insulating film 302. Therefore, etching speed increases and processing non-uniformity occurs between the peripheral edge of the product region 501 and the product region 501 on the inner side of the substrate to be processed 100 (the product region 501 not adjacent to the non-product region 502). In the CMP after the wire material film formation, an error in an abrasion rate occurs in the boundary section and processing abnormality such as remaining of the wire material in an unnecessary place occurs.

Effects of this embodiment are explained with reference to FIG. 7. In this embodiment, regardless of the fact that the exposure for processing pattern formation is applied to only the first film 304 on the product region 501, the patterns of the polystyrene (PS) sections 315 can be formed in the non-product region 502 by using the self-assembly of the block copolymer. Consequently, at a processing stage of the insulating film 302, processing of the insulating film 302 is performed in the non-product region 502 with the patterns of the polystyrene (PS) sections 315 as masks. Therefore, in the product region 501 positioned near the boundary 503 between the product region 501 and the non-product region, an appropriate amount of etchant is supplied and consumed as in the product region 501 on the inner side of the substrate to be processed 500 (the product region 501 not adjacent to the non-product region 502). Therefore, the insulating film 302 can be processed at high accuracy for both the shape of a processed pattern and a processing dimension.

In the second embodiment, patterning using self-assembly of the block copolymer is applied to the substrate peripheral edge region 102a, so that, usage of the exposing apparatus can be reduced compared with usage of the exposing apparatus that performs peripheral exposure as in the past and productivity and cost of the exposing apparatus can be improved.

In this embodiment, the negative chemically amplified resist is used as the first film 304. However, a resist that causes selective insolubility against development liquid according to simple optical crosslinking reaction without an amplification action can also be used. In this case, it is applicable that heating after exposure is not performed.

In the above explanation, the non-product region 102 (502) is the substrate peripheral edge region 102a (502a). However, even when there is the defective region 102b (502b), patterns can be formed in the defective region 102b (502b) by the same method. In this case, exposure is applied to only the product region 101, which is the circuit processing region, usage of the exposing apparatus can be reduced compared with usage of the exposing apparatus that performs peripheral exposure as in the past and productivity and cost of the exposing apparatus can be improved.

In this embodiment, after the pattern for circuit processing is formed in the product region 101 by the exposure using the negative chemically amplified resist, the self-assembled pattern is formed in the non-product region 102 by the self-assembly of the block copolymer film. However, this embodiment is not limited to this. As a modification of this embodiment, it is also possible that, after the self-assembled pattern is formed in the non-product region 102 by the self-assembly of the block copolymer film, the negative chemically amplified resist is applied on the product region 101 and the non-product region 102 and the pattern for circuit processing is formed on the product region 101 by exposure.

In this embodiment, the wafer for semiconductor manufacturing is the substrate to be processed 100. However, various applications are possible as long as the applications are for the same pattern processing for, for example, in processing of mask blanks, applying a resist to a pattern area, exposing and developing the resist to form a resist pattern, selectively applying a block copolymer to a peripheral edge of the pattern area, and performing light blocking film and substrate processing with a self-assembled pattern as a mask.

Therefore, according to the second embodiment, it is possible to efficiently form a pattern for circuit processing and perform circuit processing at high accuracy for both the shape of a processing pattern and a processing dimension using the pattern for circuit processing.

### Third Embodiment

In the third embodiment, a method of manufacturing a semiconductor device using DSA, which is an embodiment concerning Via plug formation for a lower layer wire, is explained. In this embodiment, as in the first embodiment, a block copolymer (BCP) formed by polymethyl methacrylate (PMMA) and polystyrene (PS) is selectively applied to a non-product region in a semiconductor substrate. A processing error in an etching process for a product region can be reduced by self-assembled the block copolymer and selectively removing a PMMA section. A pattern forming method that can adjust pattern coverage of the non-product region to be substantially the same as circuit pattern coverage is explained below.

In the third embodiment, as in the first embodiment, Via plugs are formed on the substrate to be processed 100 shown in FIG. 1. It is assumed that Via plugs are formed only in the product regions 101 without being formed in the non-product region 102. The non-product region 102 includes the peripheral edge region (the substrate peripheral edge region) 102a of the substrate to be processed 100 where a product (a device) is not formed and the defective region 102b that is originally the product region 101 but does not function as a product (a device) because of occurrence of a defect before a Via plug forming process. In the following explanation, the non-product region 102 is the substrate peripheral edge region 102a.

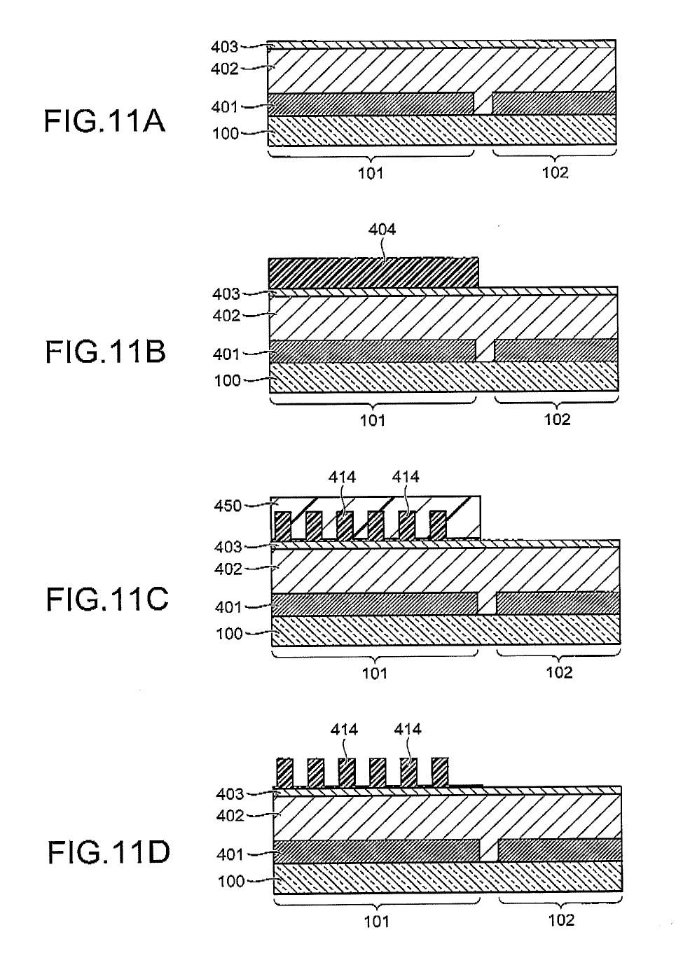

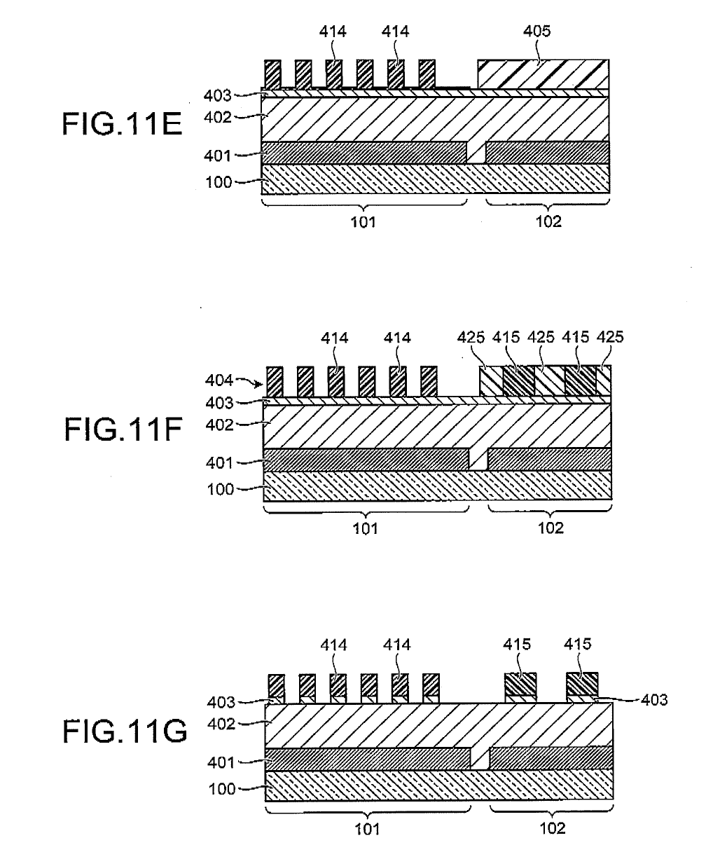

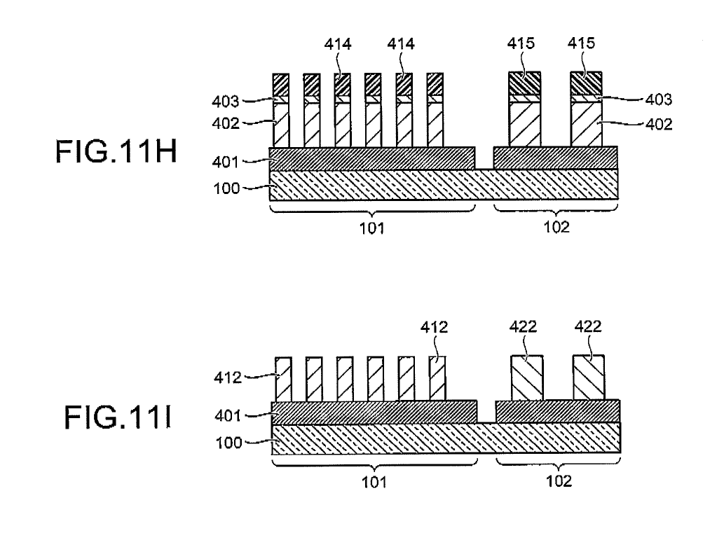

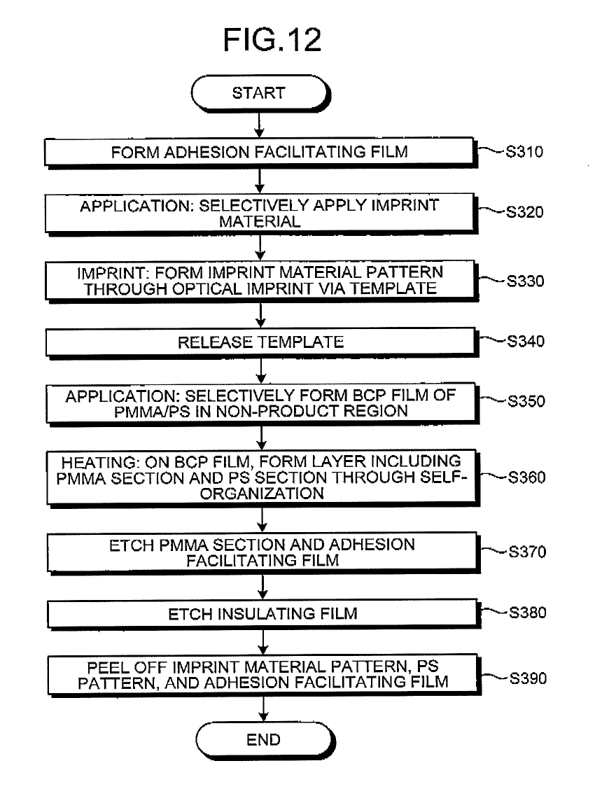

FIGS. 11A to 11J are schematic sectional views of a pattern forming process in a Via plug forming method according to the third embodiment. FIG. 12 is a flowchart for explaining a flow of the pattern forming process in the Via plug forming method according to the third embodiment.

First, the substrate to be processed 100 having a lower layer wire 401 provided on one surface and a silicon oxide film formed on the lower layer wire 401 as an insulating film 402, which is a film to be processed, is prepared. An adhesion facilitating film 403 for imprint is formed on the insulating film 402 of the substrate to be processed 100 by rotational application (step S310 in FIG. 11A). An imprint material 404 is selectively applied to the product region 101 on the adhesion facilitating film 403 by an ink-jet method (step S320 in FIG. 11B). In this embodiment, a photo-curing agent is used as the imprint material 404.

Subsequently, a photo-transmissive template 450 inscribed with a pattern for circuit processing is pressed against the imprint material 404 to spread the imprint material 404 and fill the imprint material 404 in a notch of the template 450. Light is radiated on the imprint material 404 via the template 450, whereby the imprint material 404 is photo-cured (a first film) and imprint material patterns 414 formed of the cured imprint material are formed (step S330 in FIG. 11C). Thereafter, the template 450 is released (step S340 in FIG. 11D).

A self-assembled pattern is formed in the non-product region 102 using a block copolymer. First, a second film 405 is applied on the adhesion facilitating film 403 in the non-product region 102 by a selective application method and dried (step S350 in FIG. 11E). A block copolymer (BCP) film is used for the second film 405. In this embodiment, a block copolymer film including polystyrene (PS) sections 415 and polymethyl methacrylate (PMMA) sections 425 is used as the block copolymer film. The selective film formation is performed by squeeze processing for spreading an applied film, for example, with a spatula.

A ratio of each block polymer of the block copolymer (BCP) film can be adjusted according to coverage of a pattern in the product region 101. Compositions of the block copolymers are determined such that a weight fraction of the block polymers to be removed after self-assembly is larger as the coverage of the pattern in the product region 101 is smaller. Further, compositions of the block copolymers are determined such that a weight fraction of the block polymers to be removed after self-assembly is smaller as the coverage of the pattern in the product region 101 is larger.

For example, when the coverage of the pattern in the product region 101 is about 80%, a block copolymer in which a weight fraction of polystyrene (PS) is set to 0.80 same as the coverage in the product region 101 is used. A self-assembled structure obtained from the block copolymers can be controlled by adjusting self-assembly temperature. For example, in the case of a diblock copolymer film formed by polymethyl methacrylate (PMMA) and polystyrene (PS), by adjusting the self-assembled temperature, the diblock copolymer film can be formed as a self-assembled structure in which polystyrene (PS) surrounds columnar polymethyl methacrylate (PMMA).

Subsequently, at least the substrate peripheral edge region 102a is heated to advance self-assembly in the second film 405. Consequently, the block copolymer film is divided into the polystyrene (PS) sections 415 and the polymethyl methacrylate (PMMA) sections 425 (step S360 in FIG. 11F). A structure in which the polymethyl methacrylate (PMMA) sections 425 are columnar structures upright with respect to the in-plane direction of the substrate to be processed 100 and the polystyrene (PS) sections 415 are upright with respect to the in-plane direction of the substrate to be processed 100 to surround the columnar structures is formed.

Anisotropic etching of the polymethyl methacrylate (PMMA) sections 425 and the adhesion facilitating film 403 is performed. The etching is performed by the RIE by using fluorocarbon gas and oxygen gas. In the product region 101, the adhesion facilitating film 403 and the thin imprint material film at the space area are etched and removed. In the non-product region 102, the polymethyl methacrylate (PMMA) sections 425 of the second film 405 are selectively etched and the remaining polystyrene (PS) sections 415 are formed as patterns. The exposed adhesion facilitating film 403 is etched and removed with the patterns of the polystyrene (PS) sections 415 as masks (step S370 in FIG. 11G).

Anisotropic etching of the insulating film 402 is performed. The etching is performed by the RIE using fluorocarbon gas (step S380 in FIG. 11H).

The imprint material patterns 414 used as the masks for circuit processing and the polystyrene (PS) sections 415 are removed by ashing and the adhesion facilitating film 403 is removed to form patterns of the insulating film 402 (step S390 in FIG. 11I). As the patterns of the insulating film 402, insulating film patterns 412 formed in the product region 101 and insulating film patterns 422 formed in the non-product region 102 are formed. Thereafter, after barrier metal films are formed on the surfaces of the patterns of the insulating film 402, barrier metal at the bottom is removed, metal is buried on the bottom, and a Via material formed on the outside of a via region is abraded and removed by the CMP, whereby patterns functioning as Via plugs can be formed.

As explained above, in the third embodiment, regardless of the fact that the imprint for processing pattern formation is applied to only the product region 101, the insulating film 402 can be processed at high accuracy for both the shape of a processed pattern and a processing dimension. In this embodiment, a region where foreign matters or the like are found on the substrate to be processed 100, a region where a deficiency occurs in flatness of a base film, or the like can also be included as the defective region 102b. The imprint process is not applied to such regions, it is possible to improve throughput and suppress damage to the template during pattern formation.

Influence in the case where this embodiment is not applied is explained with reference to FIG. 8. When no pattern is present in the non-product region 502, an excessively large amount of etchant is supplied from the outside of the product region 501 in the product region 501 positioned near the boundary 503 between the product region 501 and the non-product region during processing of the insulating film 402. Therefore, etching speed increases and processing non-uniformity occurs between the peripheral edge of the product region 501 and the product region 501 on the inner side of the substrate to be processed 100 (the product region 501 not adjacent to the non-product region 502). In the CMP after the Via material film formation, an error in an abrasion rate occurs in the boundary section and processing abnormality such as remaining of the Via material in an unnecessary place occurs.

Effects of this embodiment are explained with reference to FIG. 7. In this embodiment, even when the imprint is used instead of an exposure technology, a processing pattern can be formed in the product region 501 and the patterns of the polystyrene (PS) sections 415 can be formed in the non-product region 502 by using the self-assembly of the block copolymer. Consequently, at a processing stage of the insulating film 402, processing of the insulating film 402 is performed in the non-product region 502 with the patterns of the polystyrene (PS) sections 415 as masks. Therefore, in the product region 501 positioned near the boundary 503 between the product region 501 and the non-product region, an appropriate amount of etchant is supplied and consumed as in the product region 501 on the inner side of the substrate to be processed 100 (the product region 501 not adjacent to the non-product region 502). Therefore, the insulating film 402 can be processed at high accuracy for both the shape of a processed pattern and a processing dimension.

In the above explanation, the non-product region 102 is the substrate peripheral edge region 102a. However, even when there is the defective region 102b, patterns can be formed in the defective region 102b by the same method. In this case, the imprint is applied to only the product region 101, which is the circuit processing region, usage of the imprinting apparatus can be reduced compared with usage of the imprinting apparatus that performs pattern formation by peripheral exposure and productivity and cost of the imprinting apparatus can be improved.

In this embodiment, after the imprint in the product region 101 is performed, the selective supply of the block copolymer material to the substrate peripheral edge of the non-product region 102 and the self-assembly of the block copolymer material are performed. However, the imprint in the product region 101 can also be performed after the selective supply of the block copolymer material to the non-product region 102 and the self-assembly of the block copolymer material are performed.

In this embodiment, the imprint is performed by optical imprint. However, thermal imprint for curing the imprint material with heat can also be used. Moreover, when adhesion of an imprint pattern on the insulating film 402 is good and the self-assembly of the block copolymer material is possible, the adhesion facilitating film 403 can be omitted.

Therefore, according to the third embodiment, it is possible to efficiently form a pattern for circuit processing and perform circuit processing at high accuracy for both the shape of a processing pattern and a processing dimension using the pattern for circuit processing.

In the first and second embodiments, as exposing means used for the selective exposure for the first film via the photomask, it is possible to use reduced projection exposure, equal magnification exposure, or the like performed via a photomask corresponding to a circuit formation purpose using radiation such as an i ray, a g ray, KrF, ArF, or EUV as a light source. Instead of the selective exposure via the photomask, exposure can also be performed by charged particle radiation such as selective electron beam radiation by an electron beam.

In the explanation of the first to third embodiments, the diblock copolymer formed of the polystyrene (PS) sections and the polymethyl methacrylate (PMMA) sections is used as the block copolymer used for the second film. However, the block copolymer is not limited to this. Any material can be used as long as a processing resistive material having resistance against processing of a film to be processed is included in one copolymer or a processing resistant substance is captured into one copolymer side during self-assembly. In other words, as the second film, a block copolymer containing film containing such block copolymer can be used.

For example, in etching using oxygen or fluorocarbon gas, a coverage adjusted pattern formed of a polymer group including a benzene ring can be formed by using a polymer mixed film obtained by mixing a polymer including the benzene ring and a polymer not including the benzene ring and selectively removing a polymer group not including the benzene ring in the etching process after the DSA. As another example, in etching using fluorine gas, a coverage adjusted pattern formed by an organic polymer region with siloxane polymer removed can be formed by using a polymer mixed film formed of a material obtained by mixing organic polymer and the siloxane polymer.

In the first to third embodiments, the self-assembly of the block copolymer is performed by heating. However, the self-assembly of the block copolymer can also be performed in a pressed state or a solvent atmosphere of an entire substrate.

In the explanation of the first to third embodiments, the film to be processed as the processing target is the silicon oxide film. However, the film to be processed is not limited to this. As the film to be processed as the processing target, materials required to be processed for circuit manufacturing such as amorphous silicon, a silicon nitride film, a wiring material, and an electrode material can be also be used. The pattern forming methods can be carried out by variously modifying the block copolymer material, the photosensitive material, and the photo-curing agent as appropriate. It is advisable to determine selection of the block copolymer material and the block copolymer material including an additive substance according to whether a residual film amount of a self-assembled film after being subjected to an etching condition used in processing satisfies a necessary film amount.

In the first to third embodiments, it is desirable to perform pattern formation for the non-product region 102 using a block copolymer having a weight fraction corresponding to pattern coverage in the product region 101. For example, when the pattern coverage of the product region 101 is “a”, it is ideal to use a block copolymer, a weight fraction of which being selectively left in base processing is “a”, i.e., a block copolymer, a weight fraction of which being removed after the self-assembly is 1-a. It was confirmed in an experiment performed by changing a weight fraction that the object of this embodiment could be attained when a weight fraction of a polymer was in a range of +/−20% with reference to “a”. In the explanation of the embodiments, the diblock copolymer is used. However, it is possible to apply to a block copolymer or a graft copolymer formed of two or more kinds of polymer chains.

For example, when a wiring pattern (having coverage of about 50%) of a cell is formed in a product region of a NAND memory or the like, it is desirable to adjust a weight fraction of each block of a block copolymer and form the block copolymer in the lamellar structure having coverage of about 50%. When a pattern of a circuit region has a purpose of processing a base with pillars (isolated projections) as masks, because coverage is equal to or lower than 10%, it is desirable to form a section to be a mask for base processing in the spherical structure as a self-assembled structure of a block copolymer in a non-circuit region. In this way, it is desirable to design polymer compositions of each block (degrees of polymerization) according to coverage of a product circuit region such that a weight fraction of the polymer to be the mask for the base processing generally coincides with the coverage of the product circuit region and use a manufactured block copolymer. When the self-assembled structure is columnar structure or spherical structure, the self-assembled structure can be used not only in upright structure but also in arrangement such as parallel arrangement or floating arrangement.

In the first to third embodiments, a width of the self-assembled structure only has to be in a range from width equal to a circuit processing target dimension to width about 500 times as large as the circuit processing target dimension as long as predetermined coverage is satisfied.

In the first to third embodiments, the heating for causing the block copolymer to perform the self-assembly can be selected as appropriate according to process specification such as (1) heating of the entire substrate to be processed, (2) selective heating for an application region of the block copolymer by a lamp or the like, and (3) concurrent use of the heating (2) and other temperature adjustment.

When the block copolymer can take the lamellar structure or the co-continuous structure through the self-assembly, it is desirable to form the block copolymer in the lamellar structure by controlling temperature or pressure for the self-assembly. The lamellar structure is desirable as a processing mask in etching a film to be processed because an irregularity state is more clearly distinguished in the lamellar structure than in the co-continuous structure. When the block copolymer can take the columnar structure or the spherical structure through the self-assembly, it is desirable to form the block copolymer in the columnar structure by controlling temperature or pressure for the self-assembly. The columnar structure is desirable as a processing mask in etching a film to be processed because an irregularity state is more clearly distinguished in the columnar structure than in the spherical structure.

As explained above, it is also possible to evaluate, as the non-product region 102, not only the chipped shot region 504 (see FIG. 8) of the substrate peripheral edge not functioning as a device even if exposure is performed to form a circuit but also a chip region (the defective region 102b) on the inside of the substrate failing to function as a device because of a process failure or the like and apply this embodiment to the regions (see FIG. 1).

### Fourth Embodiment

In the first embodiment, the method of manufacturing a semiconductor device using a block copolymer, which is an embodiment concerning Via plug formation for a lower layer wire formed on a wafer for semiconductor manufacturing, is explained. This embodiment is different from the first embodiment in that a polymer mixed material including polymethyl methacrylate (PMMA) and polystyrene (PS) is used instead of a block copolymer. For a portion overlapping with the first embodiment, explanation is given by using the same drawings and symbols.

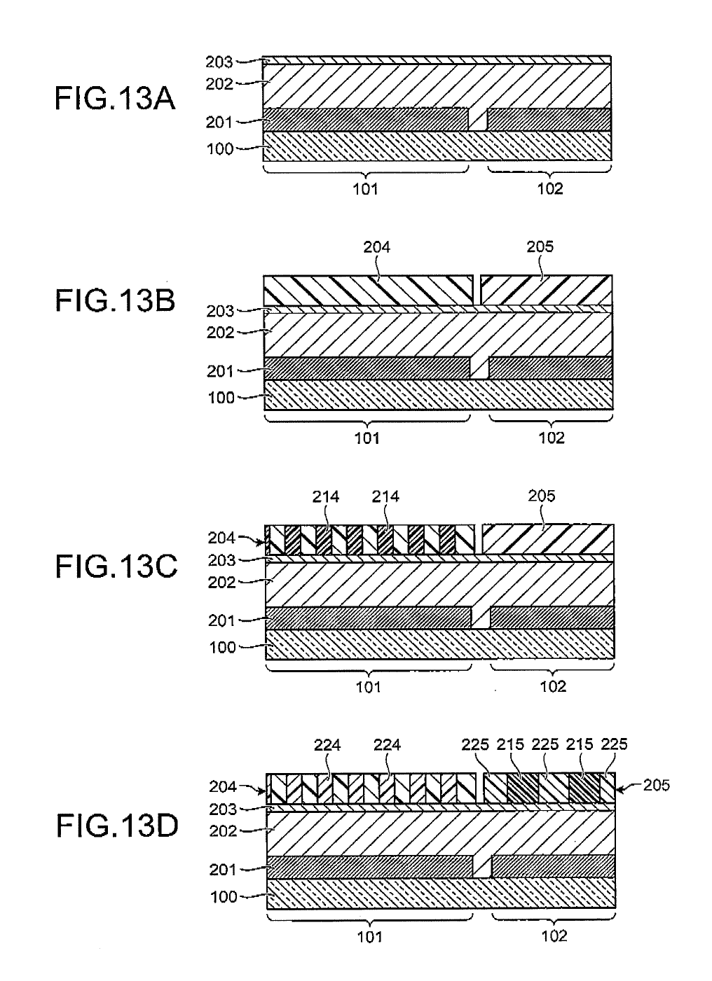

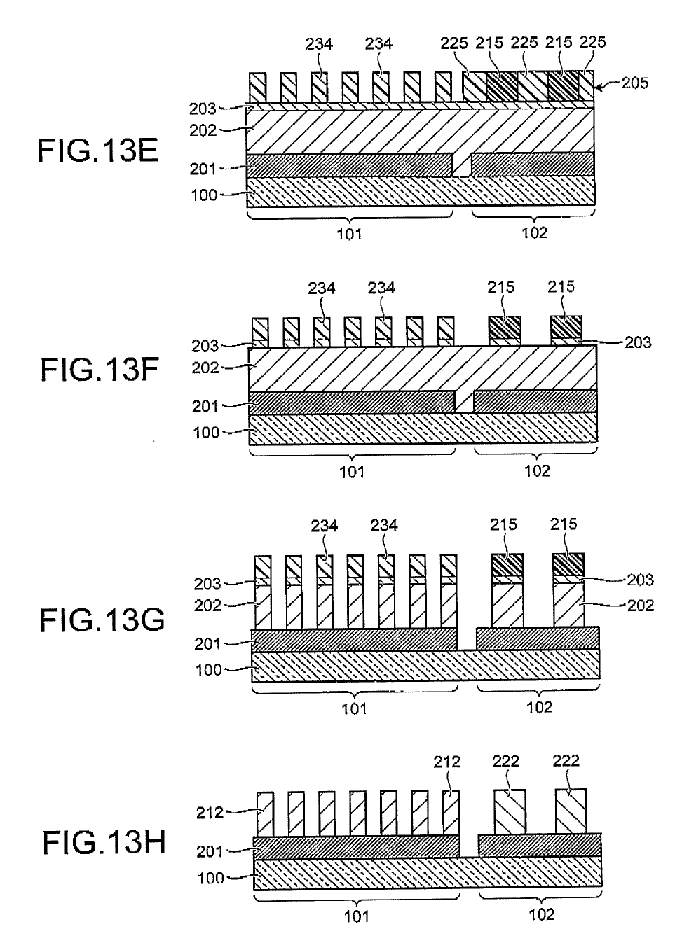

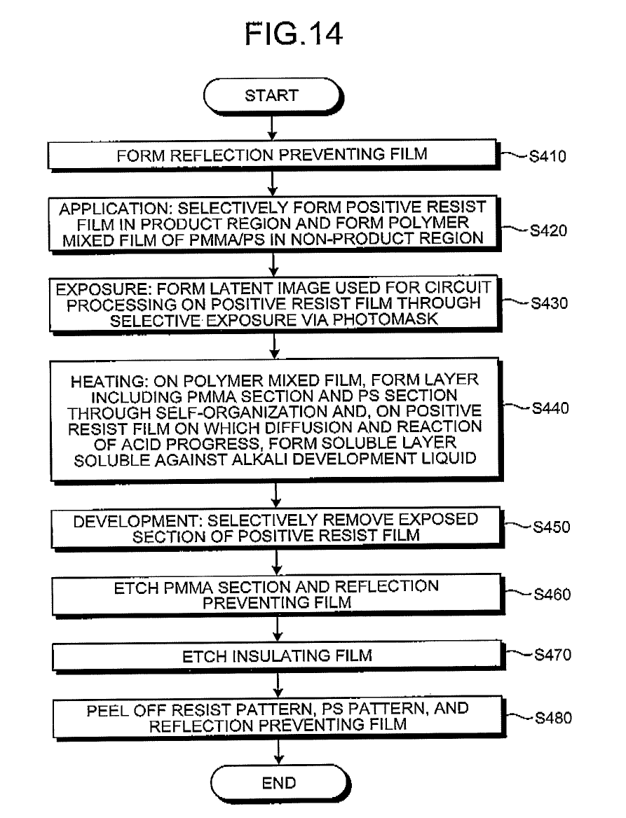

FIGS. 13A to 13H are schematic sectional views of a pattern forming process in a Via plug forming method according to this embodiment. FIG. 14 is a flowchart for explaining a flow of the pattern forming process in the Via plug forming method according to this embodiment.

First, the substrate to be processed 100 having the lower layer wire 201 provided on one surface and a silicon oxide film formed on the lower layer wire 201 as the insulating film 202, which is a film to be processed, is prepared. The antireflection film 203 is formed on the insulating film 202 of the substrate to be processed 100 by rotational application (step S410 in FIG. 13A). The first film 204 and the second film 205 are separately applied to the product region 101 and the non-product region 102 on the antireflection film 203 by a selective application method (step S420 in FIG. 13B). In other words, the first film 204 is selectively applied to the product region 101 and the second film 205 is selectively applied to the non-product region 102. The selective film formation is, for example, performed for the first film 204 by an application method by ink-jet and performed for the second film 205 by squeeze processing for further spreading an applied film formed by inkjet, for example, with a spatula.

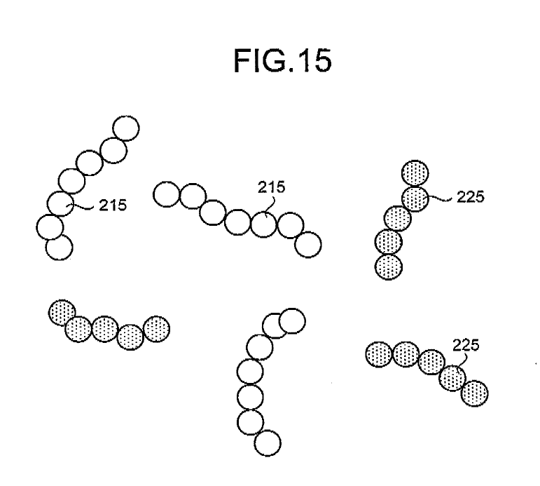

A photosensitive material film is used for the first film 204. In this embodiment, a positive chemically amplified resist film is used as the photosensitive material film. A polymer mixed film is used for the second film 205. FIG. 15 is a schematic diagram of an example of the polymer mixed film used for the second film 205. In this embodiment, as the polymer mixed film, a polymer mixed film including a polymer mixed solution (a polymer mixture) formed of a material obtained by dissolving the polystyrene (PS) sections 215 and the polymethyl methacrylate (PMMA) sections 225 in a good solvent as shown in FIG. 15 is used.

A molecular weight ratio of each polymer of the polymer mixed film can be adjusted according to coverage of a pattern in the product region 101. Compositions of the polymers are determined such that a weight fraction of the polymers to be removed after self-assembly is larger as the coverage of the pattern in the product region 101 is smaller. Further, compositions of the polymers are determined such that a weight fraction of the polymers to be removed after self-assembly is smaller as the coverage of the pattern in the product region 101 is larger. In the polymer mixture, the same structures as the block copolymer can be obtained by adjusting processing temperature and pressure. When short-time processing is performed, a mosaic pattern having an area ratio of PS:PMMA=8:2 can be obtained.

Subsequently, an exposure step for forming a latent image on the first film 204 is performed. The formation of the latent image is performed by transferring the latent images 214 used for circuit processing onto the first film 204 by selective exposure on the first film 204 via a photomask (step S430 in FIG. 13C).

A heating step for heating the substrate to be processed 100 is performed. Diffusion and reaction of acid progress in the first film 204 according to the heating step, and the soluble layers 224 soluble against development liquid are formed in exposure regions, i.e., regions where the latent images 214 are formed. Self-assembly of the polymer mixed film progresses in the second film 205 according to the heating step and the polymer mixed film is divided into the polystyrene (PS) sections 215 and the polymethyl methacrylate (PMMA) sections 225 (step S440 in FIG. 13D).

A developing step is performed by using the development liquid. The second film 205 is insoluble in the alkali development liquid. Because the first film 204 is a positive resist film, exposure section (the soluble layers 224) regions are selectively resolved in the development liquid and the positive resist patterns 234 are formed as patterns for circuit processing (step S450 in FIG. 13E).

Anisotropic etching of the polymethyl methacrylate (PMMA) sections 225 and the antireflection film 203 is performed. The etching is performed by RIE by using fluorocarbon gas and oxygen gas. In the product region 101, the exposed antireflection film 203 is etched and removed. In the non-product region 102, the polymethyl methacrylate (PMMA) sections 225 of the second film 205 are selectively etched and the remaining polystyrene (PS) sections 215 are formed as patterns. The exposed antireflection film 203 is etched and removed with the patterns of the polystyrene (PS) sections 215 as masks (step S460 in FIG. 13F).

Anisotropic etching of the insulating film 202 is performed using fluorocarbon gas (step S470 in FIG. 13G).

The positive resist patterns 234 used as the masks for circuit processing and the polystyrene (PS) sections 215 are removed by aching and the antireflection film 203 is removed to form patterns of the insulating film 202 (step S480 in FIG. 13H). As the patterns of the insulating film 202, the insulating film patterns 212 formed in the product region 101 and the insulating film patterns 222 formed in the non-product region 102 are formed. Thereafter, after barrier metal films are formed on the surfaces of the patterns of the insulating film 202, barrier metal at the bottom is removed, metal is buried on the bottom, and a film of the metal formed outside a Via region is abraded and removed by the CMP, whereby patterns functioning as Via plugs can be formed.

As explained above, in this embodiment, regardless of the fact that the exposure for processing pattern formation is applied to only the first film 204, the patterns of the polystyrene (PS) sections 215 can be formed in the non-product region 102 by using the self-assembly of the polymer mixed film. Consequently, at a processing stage of the insulating film 202, processing of the insulating film 202 is performed in the non-product region 102 with the patterns of the polystyrene (PS) sections 215 as masks. Therefore, in the peripheral edge region of the product region 101, an appropriate amount of etchant is supplied and consumed as in the product region 101 on the inner side of the substrate to be processed 100 (the product region 101 not adjacent to the non-product region 102). Therefore, the insulating film 202 can be processed at high accuracy for both the shape of a processed pattern and a processing dimension.

Patterning using self-assembly of the polymer mixed film is applied to the substrate peripheral edge region 102a, so that usage of the exposing apparatus can be reduced compared with usage of the exposing apparatus that performs peripheral exposure as in the past and productivity and cost of the exposing apparatus can be improved.

In the explanation of this embodiment, the positive chemically amplified resist is used as the first film 204. However, a negative chemically amplified resist can also be used. A resist that does not have an amplification action and causes selective solubility with respect to development liquid through simple photodecomposition or an optical crosslinking reaction can also be used.

In the above explanation, the non-product region 102 is the substrate peripheral edge region 102a. However, when there is the defective region 102b, a pattern can be formed in the defective region 102b by the same method. In this case, exposure is applied to only the product region 101, which is the circuit processing region, usage of the exposing apparatus can be reduced compared with usage of the exposing apparatus that performs peripheral exposure as in the past and productivity and cost of the exposing apparatus can be improved.

As a modification of this embodiment, after selective application of a resist film and exposure and development of a pattern for circuit processing are applied to the product region 101, selective application and self-assembly of a polymer mixed film can be applied to the non-product region 102. As another modification of this embodiment, after selective application and self-assembly of the polymer mixed film are applied to the non-product region 102, selective application of a resist film and exposure and development of a pattern for circuit processing can be applied to the product region 101. In this embodiment, the wafer for semiconductor manufacturing is the substrate to be processed 100. However, various applications are possible as long as the applications are for the same pattern processing for, for example, in processing of mask blanks, performing processing of a light blocking film and a substrate using, as a mask, a pattern self-assembled by selectively applying a resist to a pattern area and selectively applying a polymer mixed film in a peripheral edge of the pattern area.

### Fifth Embodiment

In the second embodiment, the method of manufacturing a semiconductor device using a block copolymer, which is an embodiment concerning wire formation for a lower layer wire formed on a wafer for semiconductor manufacturing, is explained. This embodiment is different from the second embodiment in that a polymer mixed material including polymethyl methacrylate (PMMA) and polystyrene (PS) is used instead of a block copolymer. For a portion overlapping with the second embodiment, explanation is given by using the same drawings and symbols.

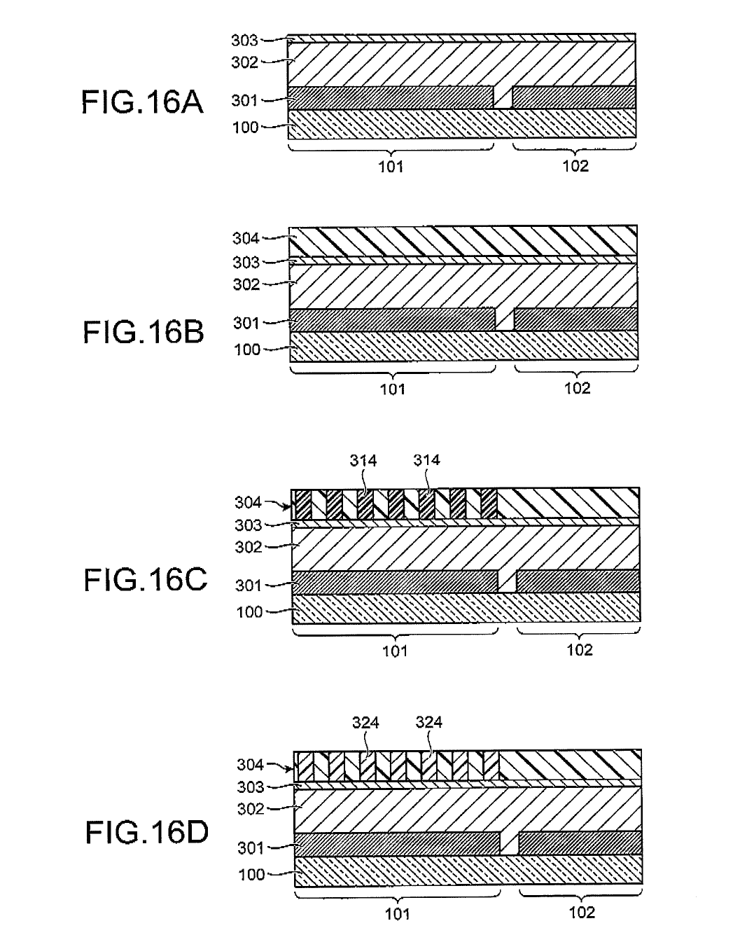

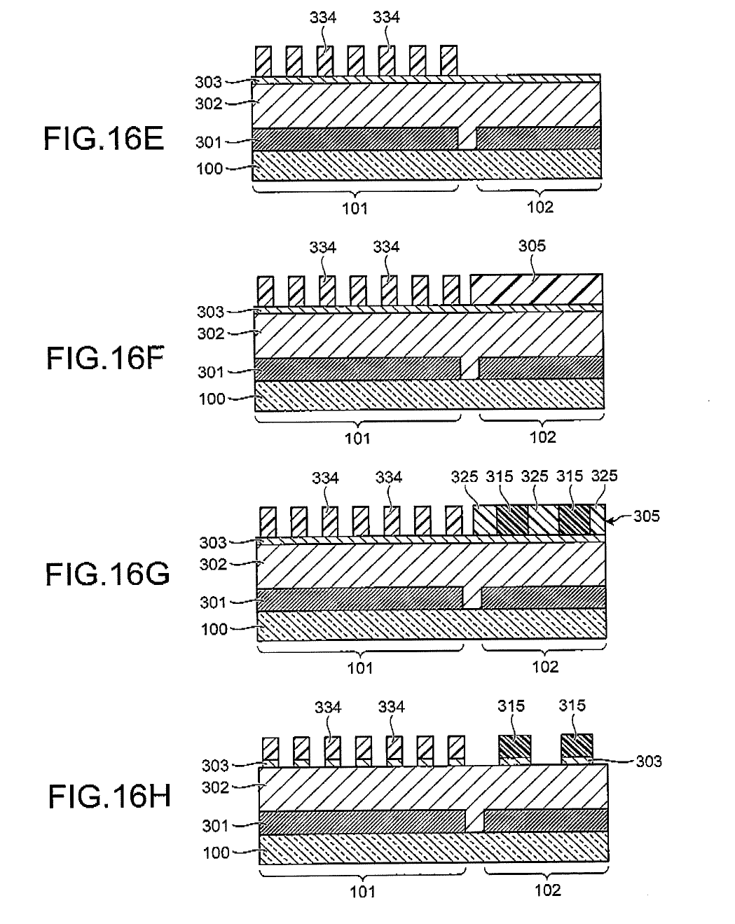

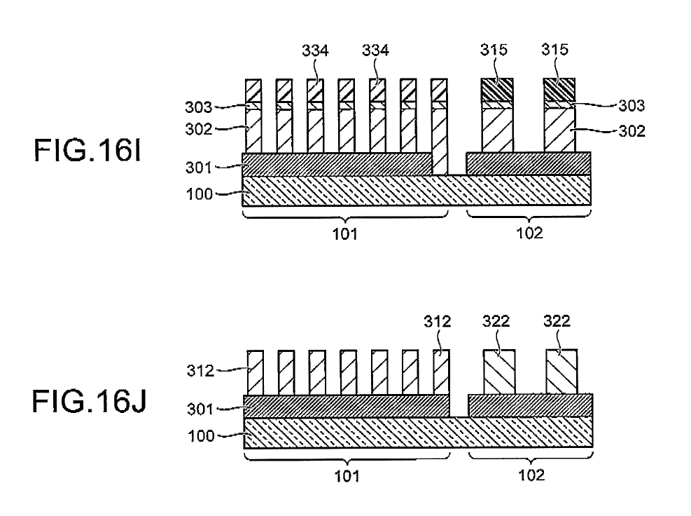

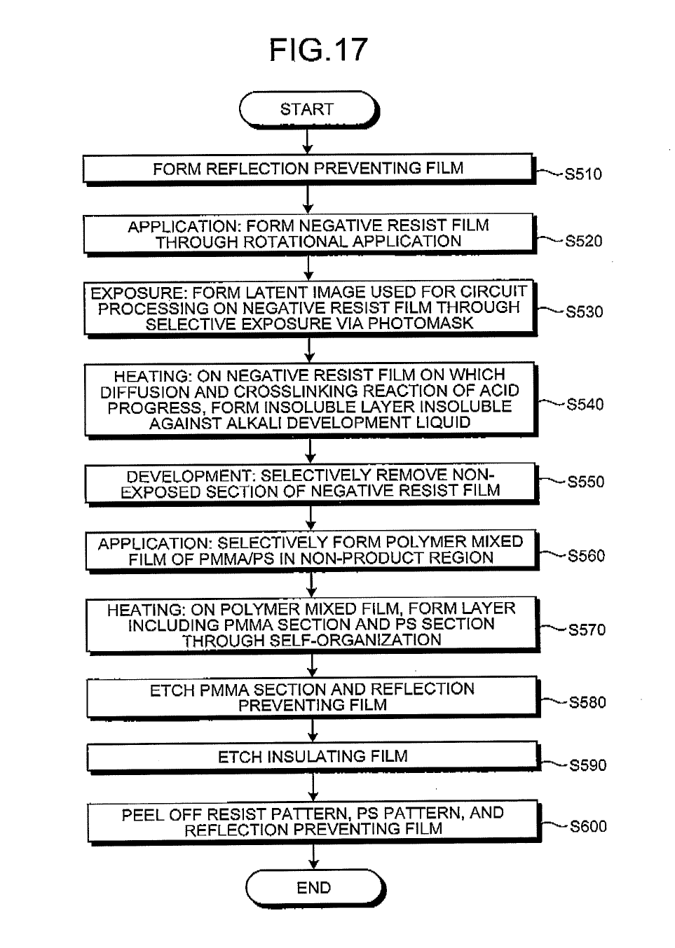

FIGS. 16A to 16J are schematic sectional views of a pattern forming process in a wire forming method according to the fifth embodiment. FIG. 17 is a flowchart for explaining a flow of the pattern forming process in the wire forming method according to the fifth embodiment.

First, the substrate to be processed 100 having the lower layer wire 301 provided on one surface and a silicon oxide film formed on the lower layer wire 301 as the insulating film 302, which is a film to be processed, is prepared. The antireflection film 303 is formed on the insulating film 302 of the substrate to be processed 100 by rotational application (step S510 in FIG. 16A). The first film 304 is applied on the antireflection film 303 by a rotational application method (step S520 in FIG. 16B). A photosensitive material film is used far the first film 304. In this embodiment, a negative chemically amplified resist film is used as the photosensitive material film.

Subsequently, an exposing step for forming a latent image in the product region 101 of the first film 304 is performed. The formation of the latent image is performed by transferring the latent images 314 used for circuit processing onto the first film 304 by selective exposure for the first film 304 via a photomask (step S530 in FIG. 16C). A latent image is not formed on the first film 304 on the non-product region 102.

A heating step for heating the substrate to be processed 100 is performed. Diffusion and crosslinking reaction of acid progress in the first film 304 according to the heating process and the insoluble layers 324 insoluble against development liquid are formed in exposure regions, i.e., regions where the latent images 314 are formed (step S540 in FIG. 16D).

A developing step is performed by using the development liquid. Because the first film 304 is a negative resist film, a region other than exposure sections (the insoluble layers 324) is selectively resolved in the development liquid and the resist patterns 334 are formed as patterns for circuit processing (step S550 in FIG. 16E). The resist film in the non-product region 102 where latent image formation is not performed is also removed by the development liquid.

A self-assembled pattern is formed in the non-product region 102 by using a polymer mixed solution. First, the second film 305 is applied on the antireflection film 303 in the non-product region 102, where the first film 304 is removed, by a selective application method and dried (step S560 in FIG. 16F). A polymer mixed film is used for the second film 305. In this embodiment, a polymer mixed film including the polystyrene (PS) sections 315 and the polymethyl methacrylate (PMMA) sections 325 is used as the polymer mixed film. The selective film formation is performed by squeeze processing for spreading an applied film with a spatula.

As in the fourth embodiment, a molecular weight ratio of each polymer of the polymer mixed film can be adjusted according to coverage of a pattern in the product region 101. Compositions of the polymers are determined such that a weight fraction of the polymers to be removed after self-assembly is larger as the coverage of the pattern in the product region 101 is smaller. Further, compositions of the polymers are determined such that a weight fraction of the polymers to be removed after self-assembly is smaller as the coverage of the pattern in the product region 101 is larger.

Subsequently, at least the substrate peripheral edge region 102a is heated to advance self-assembly in the second film 305. Consequently, the polymer mixed film is divided into the polystyrene (PS) sections 315 and the polymethyl methacrylate (PMMA) sections 325 and a lamellar structure in which the polystyrene (PS) sections 315 and the polymethyl methacrylate (PMMA) sections 325 are upright with respect to the in-plane direction of the substrate to be processed 100 is formed (step S570 in FIG. 16G).

Anisotropic etching of the polymethyl methacrylate (PMMA) sections 325 and the antireflection film 303 is performed. The etching is performed by the RIE by using fluorocarbon gas and oxygen gas. In the product region 101, the exposed antireflection film 303 is etched and removed. In the non-product region 102, the polymethyl methacrylate (PMMA) sections 325 of the second film 305 are selectively etched and the remaining polystyrene (PS) sections 315 are formed as patterns. The exposed antireflection film 303 is etched and removed with the patterns of the polystyrene (PS) sections 315 as masks (step S530 in FIG. 16H).

Subsequently, anisotropic etching of the insulating film 302 is performed by using fluorocarbon gas (step S590 in FIG. 16I).

The resist patterns 334 used as the masks for circuit processing and the polystyrene (PS) sections 315 are removed by aching and the antireflection film 303 is removed to form patterns of the insulating film 302 (step S600 in FIG. 16J). As the patterns of the insulating film 302, the insulating film patterns 312 formed in the product region 101 and the insulating film patterns 322 formed in the non-product region 102 are formed. Thereafter, after barrier metal films are formed on the surfaces of the insulating film patterns 312, barrier metal at the bottom is removed, metal is buried on the bottom, and a wire material formed on the outside of a wire region is abraded and removed by the CMP, whereby patterns functioning as wires can be formed.

As explained above, in this embodiment, regardless of the fact that the exposure for processing pattern formation is applied to only the first film 304 on the product region 101, the patterns of the polystyrene (PS) sections 315 can be formed in the non-product region 102 by using the self-assembly of the polymer mixed film. Consequently, at a processing stage of the insulating film 302, processing of the insulating film 302 is performed in the non-product region 102 with the patterns of the polystyrene (PS) sections 315 as masks. Therefore, in the peripheral edge region of the product region 101, an appropriate amount of etchant is supplied and consumed as in the product region 101 on the inner side of the substrate to be processed 100 (the product region 101 not adjacent to the non-product region 102). Therefore, the insulating film 302 can be processed at high accuracy for both the shape of a processed pattern and a processing dimension. Moreover, effects same as those in the second embodiment can be obtained.

In this embodiment, after the pattern for circuit processing is formed in the product region 101 by the exposure using the negative chemically amplified resist, the self-assembled pattern is formed in the non-product region 102 by the self-assembly of the polymer mixed film. However, this embodiment is not limited to this. As a modification of this embodiment, it is also possible that, after the self-assembled pattern is formed in the non-product region 102 by the self-assembly of the polymer mixed film, the negative chemically amplified resist is applied on the product region 101 and the non-product region 102 and the pattern for circuit processing is formed on the product region 101 by exposure.

In this embodiment, the wafer for semiconductor manufacturing is the substrate to be processed 100. However, various applications are possible as long as the applications are for the same pattern processing for, for example, in processing of mask blanks, applying a resist to a pattern area, exposing and developing the resist to form a resist pattern, selectively applying a polymer mixed material to a peripheral edge of the pattern area to form a polymer mixed film, and performing light blocking film and substrate processing with the self-assembled pattern as a mask.

### Sixth Embodiment

In the third embodiment, the method of manufacturing a semiconductor device using a block copolymer, which is an embodiment concerning a pattern forming method using an imprint method, is explained. This embodiment is different from the third embodiment in that a polymer mixed material including polymethyl methacrylate (PMMA) and polystyrene (PS) is used instead of a block copolymer. For a portion overlapping with the third embodiment, explanation is given by using the same drawings and symbols.

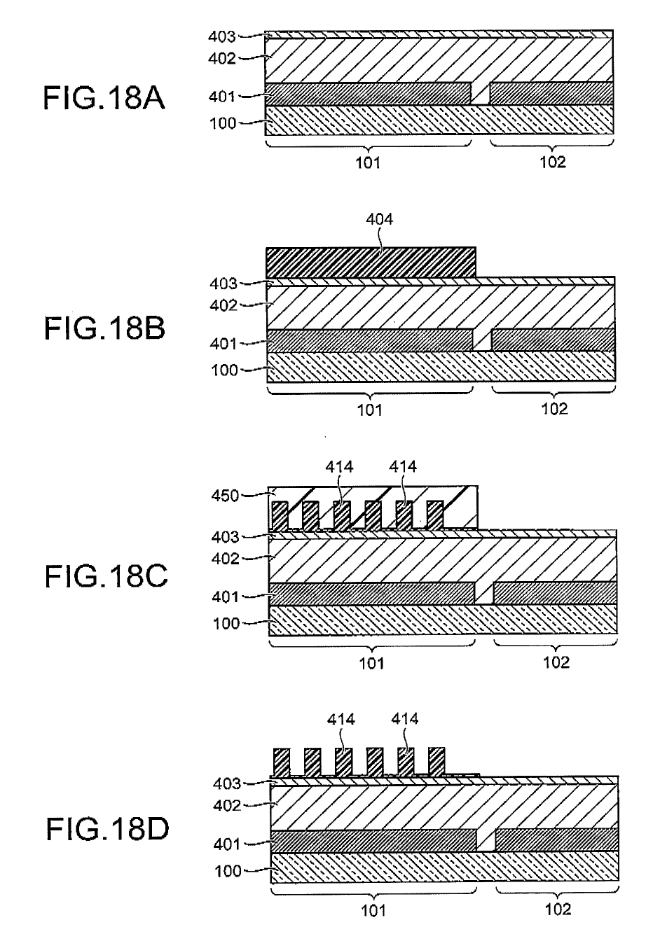

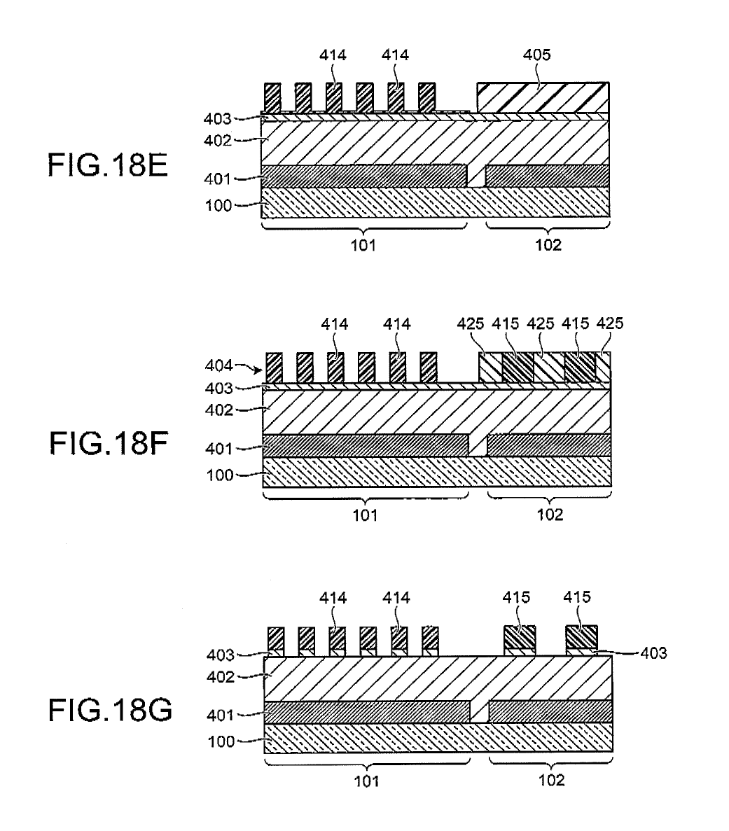

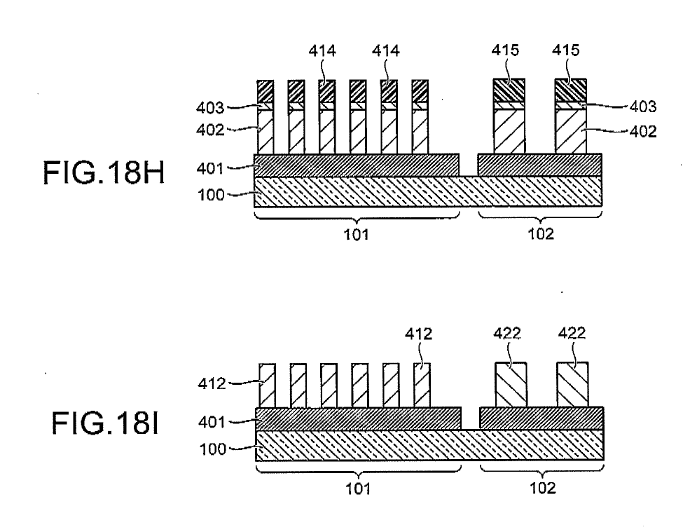

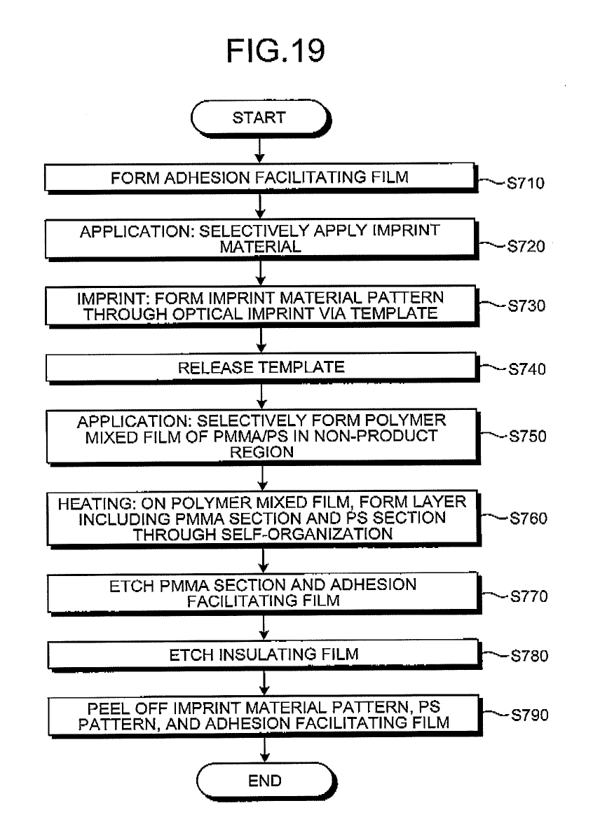

FIGS. 18A to 18I are schematic sectional views of a pattern forming process in a Via plug forming method according to the sixth embodiment. FIG. 19 is a flowchart for explaining a flow of the pattern forming process in the Via plug forming method according to the sixth embodiment.

First, the substrate to be processed 100 having the lower layer wire 401 provided on one surface and a silicon oxide film formed on the lower layer wire 401 as the insulating film 402, which is a film to be processed, is prepared. The adhesion facilitating film 403 for imprint is formed on the insulating film 402 of the substrate to be processed 100 by rotational application (step S710 in FIG. 18A). The imprint material 404 is selectively applied to the product region 101 on the adhesion facilitating film 403 by an ink-jet method (step S720 in FIG. 18B). In this embodiment, a photo-curing agent is used as the imprint material 404.

Subsequently, the photo-transmissive template 450 inscribed with a pattern for circuit processing is pressed against the imprint material 404 to spread the imprint material 404 and fill the imprint material 404 in a notch of the template 450. Light is radiated on the imprint material 404 via the template 450, whereby the imprint material 404 is photo-cured (a first film) and the imprint material patterns 414 formed of the cured imprint material are formed (step S730 in FIG. 18C). Thereafter, the template 450 is released (step S740 in FIG. 18D). A self-assembled pattern is formed in the non-product region 102 using a polymer mixed film. First, the second film 405 is applied on the adhesion facilitating film 403 in the non-product region 102 by a selective application method and dried (step S750 in FIG. 18E). A polymer mixed film is used for the second film 405. In this embodiment, a film on which a polymer mixed solution formed of the polystyrene (PS) sections 415 and the polymethyl methacrylate (PMMA) sections 425 is applied is used as the polymer mixed film. The selective film formation is performed by squeeze processing for spreading an applied film, for example, with a spatula.

A molecular weight ratio of each polymer of the polymer mixed film can be adjusted according to coverage of a pattern in the product region 101. Compositions of the polymers are determined such that a weight fraction of the polymers to be removed after self-assembly is larger as the coverage of the pattern in the product region 101 is smaller. Further, compositions of the polymers are determined such that a weight fraction of the polymers to be removed after self-assembly is smaller as the coverage of the pattern in the product region 101 is larger.

Subsequently, at least the substrate peripheral edge region 102a is heated to advance self-assembly in the second film 405. Consequently, the polymer mixed film is divided into the polystyrene (PS) sections 415 and the polymethyl methacrylate (PMMA) sections 425 (step S760 in FIG. 18F). A structure in which the polymethyl methacrylate (PMMA) sections 425 are columnar structures upright with respect to the in-plane direction of the substrate to be processed 100 and the polystyrene (PS) sections 415 are upright with respect to the in-plane direction of the substrate to be processed 100 to surround the columnar structures is formed.

Anisotropic etching of the polymethyl methacrylate (PMMA) sections 425 and the adhesion facilitating film 403 is performed. The etching is performed by the RIE by using fluorocarbon gas and oxygen gas. In the product region 101, the exposed adhesion facilitating film 403 and thin imprint material film at the space area are etched and removed. In the non-product region 102, the polymethyl methacrylate (PMMA) sections 425 of the second film 405 are selectively etched and the remaining polystyrene (PS) sections 415 are formed as patterns. The adhesion facilitating film 403 is etched and removed with the patterns of the polystyrene (PS) sections 415 as masks (step S770 in FIG. 18G).

Anisotropic etching of the insulating film 402 is performed by using fluorocarbon gas (step S780 in FIG. 18H).

The imprint material patterns 414 used as the masks for circuit processing and the polystyrene (PS) sections 415 are removed by ashing and the adhesion facilitating film 403 is removed to form patterns of the insulating film 402 (step S790 in FIG. 18I). As the patterns of the insulating film 402, the insulating film patterns 412 formed in the product region 101 and the insulating film patterns 422 formed in the non-product region 102 are formed. Thereafter, after barrier metal films are formed on the surfaces of the patterns of the insulating film 402, barrier metal at the bottom is removed, metal is buried on the bottom, and a Via material formed on the outside of a Via region is abraded and removed by the CMP, whereby patterns functioning as Via plugs can be formed.

As explained above, in this embodiment, even when the imprint is used instead of an exposure technology, a processing pattern can be formed in the product region 101 and the patterns of the polystyrene (PS) sections 415 can be formed in the non-product region 102 by using the self-assembly of the polymers. Consequently, at a processing stage of the insulating film 402, processing of the insulating film 402 is performed in the non-product region 102 with the patterns of the polystyrene (PS) sections 415 as masks. Therefore, in the peripheral edge region of the product region 101, an appropriate amount of etchant is supplied and consumed as in the product region 101 on the inner side of the substrate to be processed 100 (the product region 101 not adjacent to the non-product region 102). Therefore, the insulating film 402 can be processed at high accuracy for both the shape of a processed pattern and a processing dimension.

In this embodiment, the non-product region 102 is the substrate peripheral edge region 102a. However, even when there is the defective region 102b, patterns can be formed in the defective region 102b by the same method. In this case, the imprint is applied to only the product region 101, which is the circuit processing region, usage of the imprinting apparatus can be reduced compared with usage, of the imprinting apparatus that performs pattern formation by peripheral exposure and productivity and cost of the imprinting apparatus can be improved.

In this embodiment, after the imprint in the product region 101 is performed, the selective supply of the polymer mixed material to the substrate peripheral edge section of the non-product region 102 and the self-assembly of the polymer mixed material are performed. However, the imprint in the product region 101 can also be performed after the selective supply of the polymer mixed material to the non-product region 102 and the self-assembly of the polymer mixed material are performed.

In this embodiment, the imprint is performed by optical imprint. However, thermal imprint for curing the imprint material with heat can also be used. Moreover, when adhesion of an imprint pattern on the insulating film 402 is good and the self-assembly of the polymer mixed film is possible, the adhesion facilitating film 403 can be omitted.

In the explanation of the fourth to sixth embodiments, the polymer mixed material formed of the polystyrene (PS) sections and the polymethyl methacrylate (PMMA) sections is used as the polymer mixed material used for the second film. However, the polymer mixed material is not limited to this. Any material can be used as long as a processing resistive material having resistance against processing of a film to be processed is included in one polymer or a processing resistant substance is captured into one polymer side during self-assembly. In other words, as the second film, a polymer containing film containing such polymer can be used. In the above embodiments, the self-assembly of the polymer mixed film is performed by heating. However, the self-assembly of the polymer mixed film can also be performed in a pressed state of an entire substrate.

In the explanation of the fourth to sixth embodiments, the polymer mixed film of polymethyl methacrylate and polystyrene is used. However, the polymer mixed film is not limited to this. It is possible to obtain effects substantially the same as those in the first to third embodiments by using a polymer mixed film including at least two kinds of polymers having different etching speeds with respect to etching gas (accurately, etchant) used for removal of one polymer after the self-assembly.

For example, in etching using oxygen or fluorocarbon gas, a coverage adjusted pattern formed of a polymer group including a benzene ring can be formed by using a polymer mixed film obtained by mixing a polymer including the benzene ring and a polymer not including the benzene ring and selectively removing a polymer group not including the benzene ring in the etching process after the DSA. As another example, in etching using fluorine gas, a coverage adjusted pattern formed by an organic polymer section with siloxane polymer removed can be formed by using a polymer mixed film formed of a material obtained by mixing organic polymer and the siloxane polymer.

### Seventh Embodiment

In the first to sixth embodiments, the embodiments of selectively etching the self-assembled polymer film by the RIE and forming a pattern in the non-product region are explained. This embodiment is different from the first to sixth embodiments in that the self-assembled polymer film is selectively etched by WET etching to form patterns in the non-product region. For a portion overlapping with the first to sixth embodiments, explanation is given by using the same drawings and symbols.

In the seventh embodiment, wires are formed on the substrate to be processed 100 shown in FIG. 1. It is assumed that wires are formed only in the product region 101 without being formed in the non-product region 102. In the following explanation, the non-product region 102 is the substrate peripheral edge region 102a.

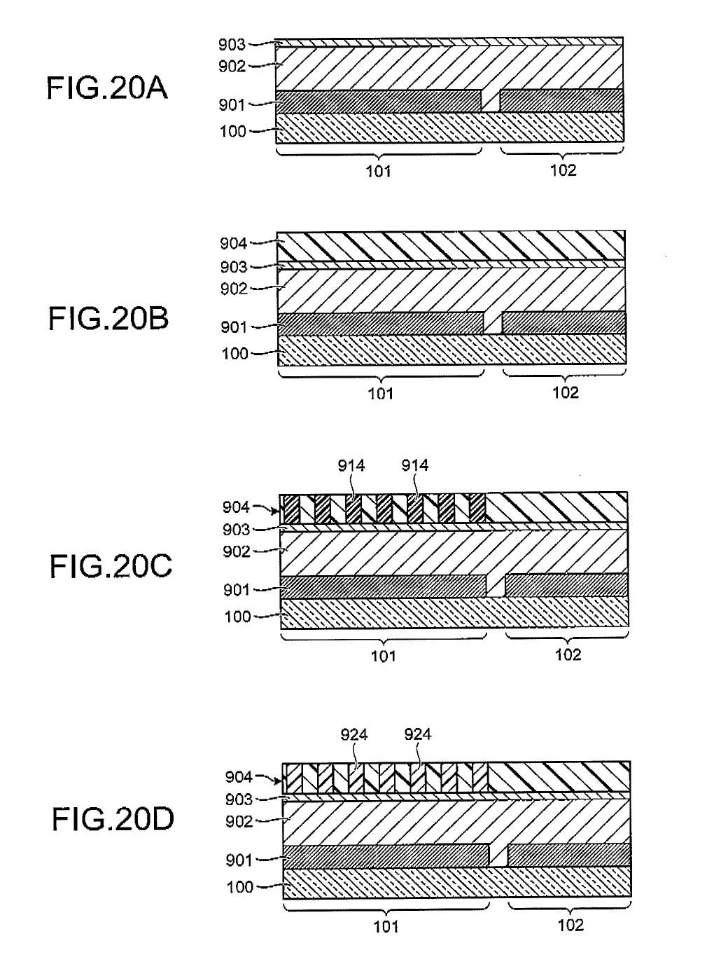

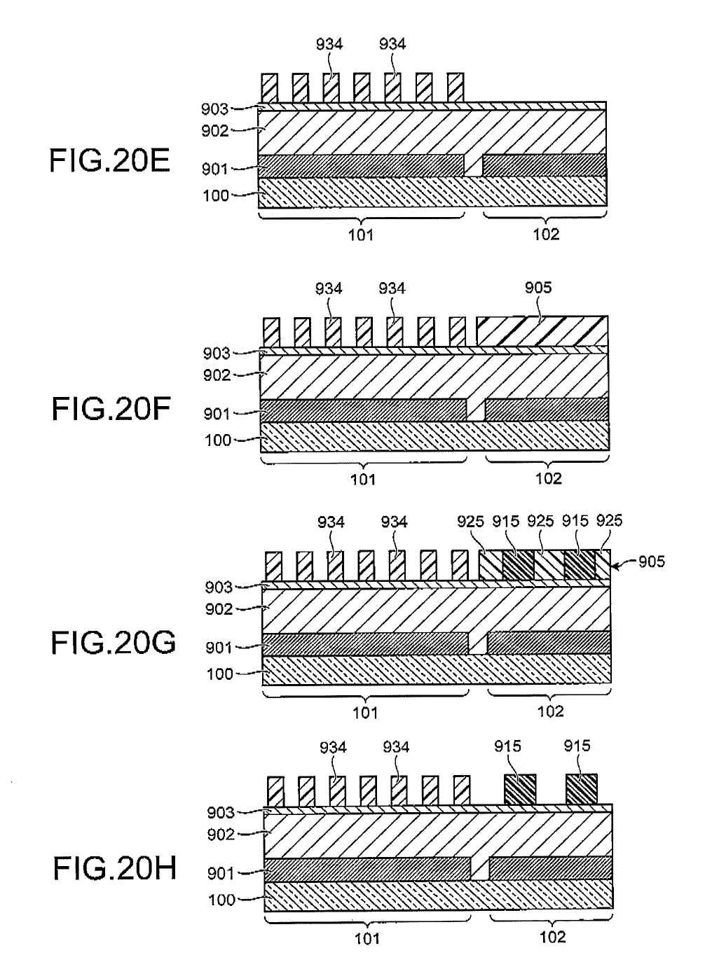

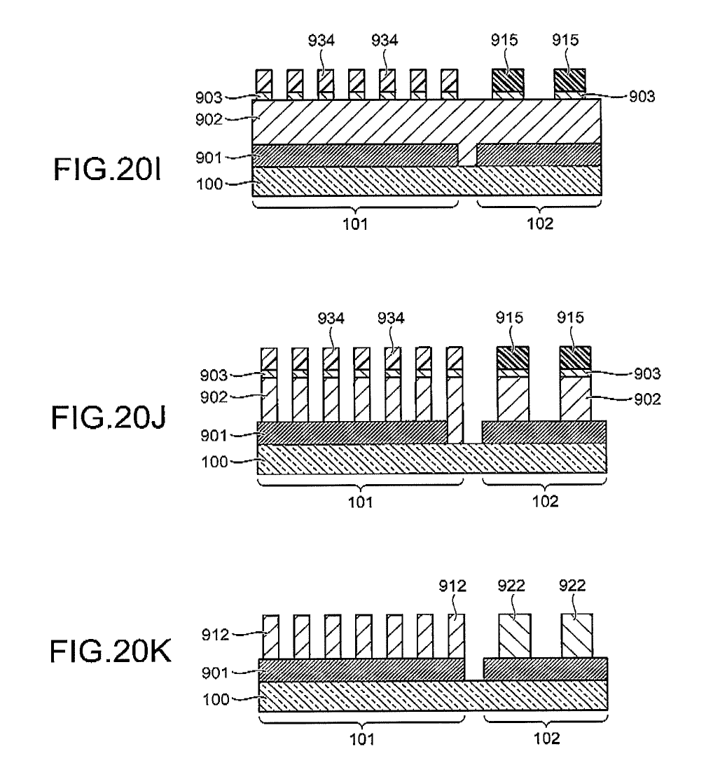

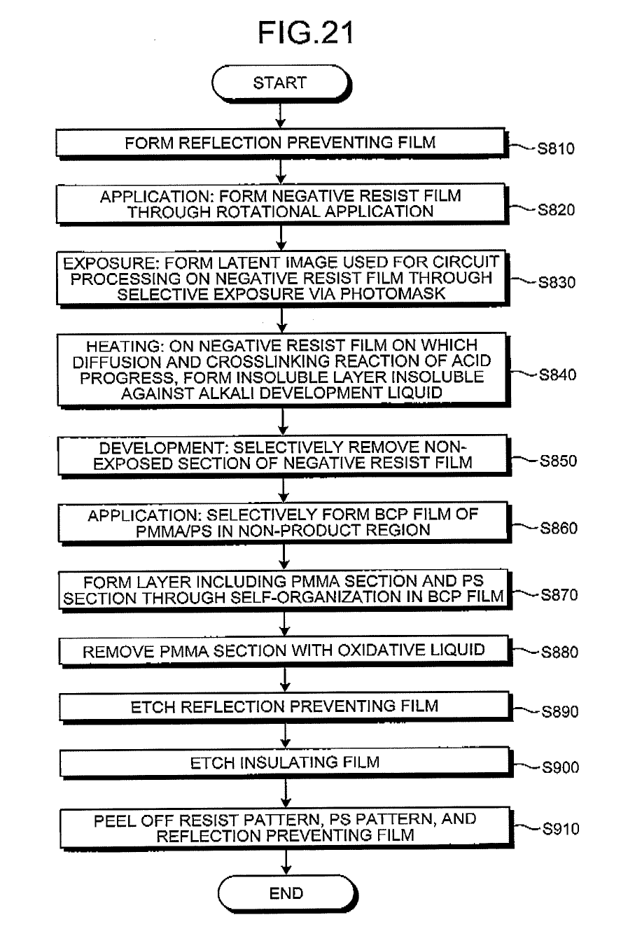

FIGS. 20A to 20K are schematic sectional views of a pattern forming process in a wire forming method according to the seventh embodiment. FIG. 21 is a flowchart for explaining a flow of the pattern forming process in the wire forming method according to the seventh embodiment. First, the substrate to be processed 100 having a lower layer wire 901 provided on one surface and a silicon oxide film formed on the lower layer wire 901 as an insulating film 902, which is a film to be processed, is prepared. A antireflection film 903 is formed on the insulating film 902 of the substrate to be processed 100 by rotational application (step S810 in FIG. 20A). A first film 904 is applied on the antireflection film 903 by a rotational application method (step S820 in FIG. 20B). A photosensitive material film is used for the first film 904. In this embodiment, a negative chemically amplified resist film is used as the photosensitive material film.

Subsequently, an exposing step for forming a latent image in the product region 101 of the first film 904 is performed. The formation of the latent image is performed by transferring latent images 914 used for circuit processing onto the first film 904 by selective exposure for the first film 904 via a photomask (step S830 in FIG. 20C). A latent image is not formed on the resist film on the non-product region 102.

A heating step for heating the substrate to be processed 100 is performed. Diffusion and crosslinking reaction of acid progress in the first film 904 according to the heating process and insoluble layers 924 insoluble against development liquid are formed in exposure regions, i.e., regions where the latent images 914 are formed (step S840 in FIG. 20D). A developing step is performed by using the development liquid. Because the first film 904 is a negative resist film, a region other than exposure sections (the insoluble layers 924) is selectively resolved in the development liquid and negative resist patterns 934 are formed as patterns for circuit processing (step S850 in FIG. 20E). The resist film in the non-product region 102 where latent image formation is not performed is also removed by the development liquid.

A self-assembled pattern is formed in the non-product region 102 by using a block copolymer. First, a second film 905 is applied on the antireflection film 903 in the non-product region 102, where the first film 904 is removed, by a selective application method and dried (step S860 in FIG. 20F). A block copolymer (BCP) film is used for the second film 905. In this embodiment, a diblock copolymer film including polystyrene (PS) sections 915 and polymethyl methacrylate (PMMA) sections 925 is used as the block copolymer film. The selective film formation is performed by squeeze processing for spreading an applied film with a spatula.

A molecular weight ratio of each block polymer of the block copolymer (BCP) film can be adjusted according to coverage of a pattern in the product region 101. Compositions of the block copolymers are determined such that a weight fraction of the block polymers to be removed after self-assembly is larger as the coverage of the pattern in the product region 101 is smaller. Further, compositions of the block copolymers are determined such that a weight fraction of the block polymers to be removed after self-assembly is smaller as the coverage of the pattern in the product region 101 is larger.

Subsequently, at least the substrate peripheral edge region 102a is heated to advance self-assembly in the second film 905. Consequently, the block copolymer film is divided into the polystyrene (PS) sections 915 and the polymethyl methacrylate (PMMA) sections 925 and a lamellar structure in which the polystyrene (PS) sections 915 and the polymethyl methacrylate (PMMA) sections 925 are upright with respect to the in-plane direction of the substrate to be processed 100 is formed (step S870 in FIG. 20G).

Oxidative liquid is supplied to at least the substrate peripheral edge region 102a and the polymethyl methacrylate (PMMA) sections 925 of the self-assembled film are oxidized and removed. It is advisable to use ozone water, hydrogen peroxide water, or the like as the oxidative liquid. When oxidation power of the oxidative liquid is not enough for oxidizing and removing PMMA, additional processing such as substrate heating, heating of the oxidative liquid, or processing for radiating UV light to generate active radical in the oxidative liquid while supplying the oxidative liquid to the self-assembled film can be added. Concentration of an oxidative substance in the oxidative liquid (ozone in the case of the ozone water or hydrogen peroxide in the case of the hydrogen peroxide water), a temperature condition during the heating, and a condition during the UV light radiation can be any values as long as a selection ratio of PMMA and PS can be obtained to some degree and a dimension fluctuation amount that occurs in a negative resist pattern is within an allowable range (step S880 in FIG. 20H).

As a modification of this embodiment, it is possible that acid liquid is supplied instead of oxidative liquid, hydrolysis is performed in the polymethyl methacrylate (PMMA) sections 925 of the self-assembled film, and the PMMA sections are resolved in water. As the acid liquid, sulfuric acid, hydrochloric acid, or the like can be used. When the hydrolysis does not occur enough for removing PMMA, heating such as substrate heating or heating of the acid liquid can also be performed. Concentration of the acid liquid and a temperature condition during the heating can be any values as long as PMMA causes hydrolysis and a dimension fluctuation amount that occurs in a negative resist pattern is within an allowable range.

Anisotropic etching of the antireflection film 903 is performed with the negative resist patterns 934 and the patterns of the polystyrene (PS) sections 915 as masks. The etching is performed by the RIE by using fluorocarbon gas and oxygen gas. In the product region 101, the antireflection film 903 is etched and removed with the negative resist patterns 934, which are the patterns for circuit processing, as masks. In the non-product region 102, the antireflection film 903 is etched and removed with the patterns of the polystyrene (PS) sections 915 as masks. (step S890 in FIG. 20I).

Anisotropic etching of the insulating film 902 is performed using fluorocarbon gas (step S900 in FIG. 20J). The negative resist patterns 934 used as the masks for circuit processing and the polystyrene (PS) sections 915 are removed by ashing and the antireflection film 903 is removed to form patterns of the insulating film 902 (step S910 in FIG. 20K). As the patterns of the insulating film 902, insulating film patterns 912 formed in the product region 101 and insulating film patterns 922 formed in the non-product region 102 are formed. Thereafter, after barrier metal films are formed on the surfaces of the patterns of the insulating film 902, barrier metal at the bottom is removed, metal is buried on the bottom, and a wire material formed on the outside of a wire region is abraded and removed by the CMP, whereby patterns functioning as wires can be formed.

When no pattern is present in the non-product region 102, in the CMP after the wire material film formation, an error in an abrasion rate occurs at the boundary between the non-product region 102 and the peripheral edge of the product region 101 and processing abnormality such as remaining of the wire material in an unnecessary place occurs. However, in this embodiment, regardless of the fact that the exposure for processing pattern formation is applied to only the first film 904, the patterns of the polystyrene (PS) sections 915 can be formed in the non-product region 102 by using the self-assembly of the block copolymer. Consequently, at a processing stage of the insulating film 902, processing of the insulating film 902 is performed in the non-product region 102 with the patterns of the polystyrene (PS) sections 915 as masks. Therefore, processing can be performed without causing the processing abnormality such as remaining of the wire material in an unnecessary place.

In this embodiment, the negative chemically amplified resist is used as the first film 904. However, a resist that causes selective insolubility against development liquid according to simple optical crosslinking reaction without an amplification action can also be used. In the case, it is applicable that heating after exposure is not performed.

In this embodiment, the pattering in the product region is performed by exposure using the negative chemically amplified resist in the first film 904. However, a pattern can also be formed by an optical or thermal imprint method.

In this embodiment, the patterning in the product region is performed by exposure using the negative chemically amplified resist in the first film 904. However, the patterning can also be performed by exposure by selectively applying a positive resist (a chemically amplified positive resist is acceptable) in an exposure region.

In the above explanation, the non-product region 102 is the substrate peripheral edge region 102a. However, even when there is the defective region 102b, a pattern can be formed in the defective region 102b by the same method.

In this embodiment, the wafer for semiconductor manufacturing is the substrate to be processed 100. However, various applications are possible as long as the applications are for the same pattern processing for, for example, in processing of mask blanks, applying a resist to a pattern area, exposing and developing the resist to form a resist pattern, selectively applying a block copolymer to a peripheral edge of the pattern area and performing light blocking film and substrate processing with the self-assembled pattern as a mask.

The diblock copolymer used in this embodiment is a copolymer of PS and PMMA. However, the diblock copolymer is not limited to this. A diblock copolymer, a triblock copolymer, or a mixed copolymer of the diblock copolymer and the triblock copolymer can be used as long as the diblock copolymer is a block copolymer including a block polymer not oxidatively destructed by oxidative liquid and a block polymer oxidatively destructed by the oxidative liquid. Moreover, a polymer mixed solution (a polymer mixture) in which PS and PMMA are resolved can be used. The combination of the polymer mixture is not limited to PS and PMMA and can be appropriately changed.

### Eighth Embodiment

In the eighth embodiment, a method of manufacturing a semiconductor device using DSA, which is an embodiment concerning wire formation for a lower layer wire, is explained. In this embodiment, a block copolymer (BCP) formed by polystyrene (PS) and polydimethyl siloxane (PDMS) is selectively applied to a non-product region in a semiconductor substrate. A processing error in an etching process for a product region can be reduced by self-assembled the block copolymer and selectively removing a PS section. A pattern forming method that can adjust pattern coverage of the non-product region to be substantially the same as circuit pattern coverage without using exposure is explained below.

In the eighth embodiment, wires are formed on the substrate to be processed 100 shown in FIG. 1. It is assumed that wires are formed only in the product region 101 without being formed in the non-product region 102. In the following explanation, the non-product region 102 is the substrate peripheral edge region 102a.

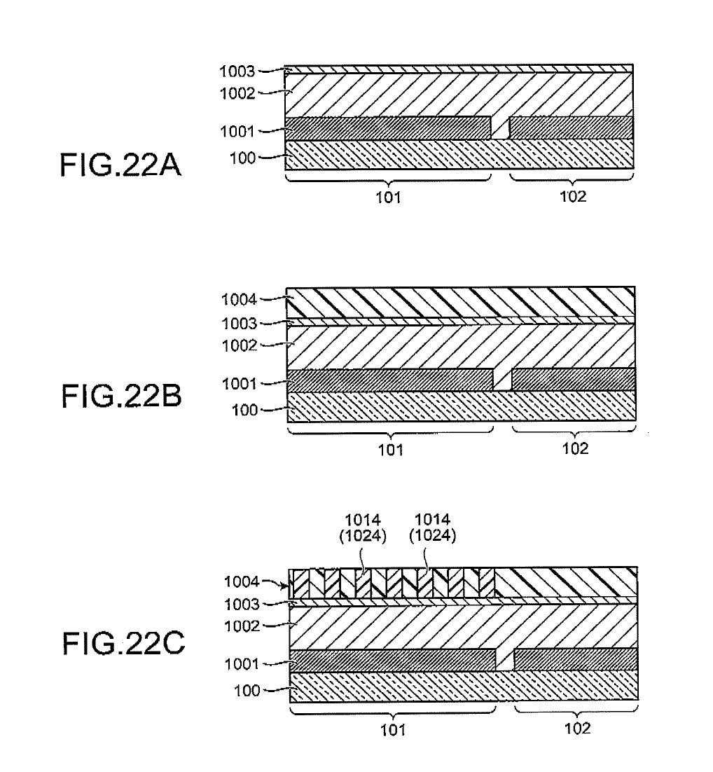

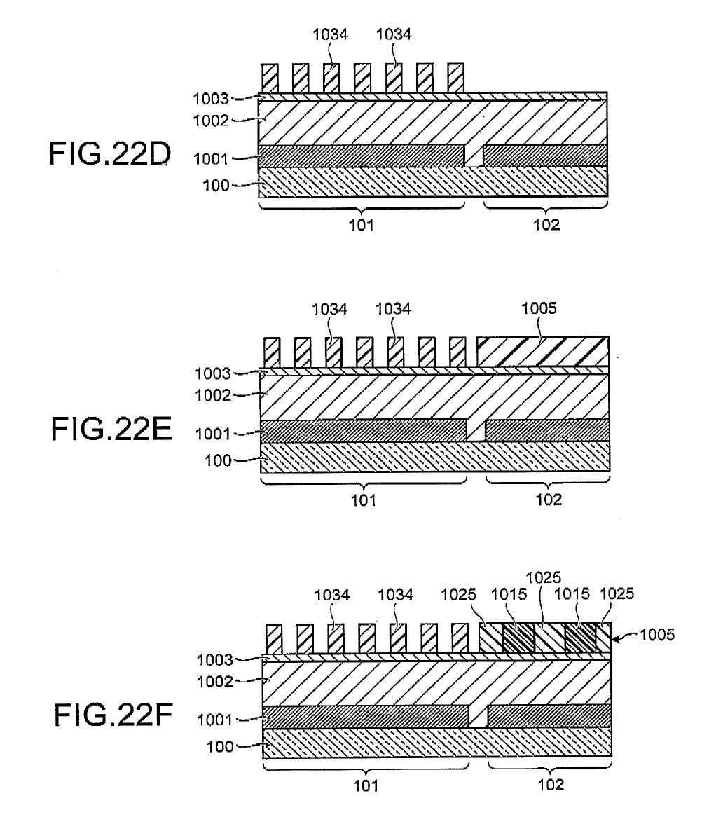

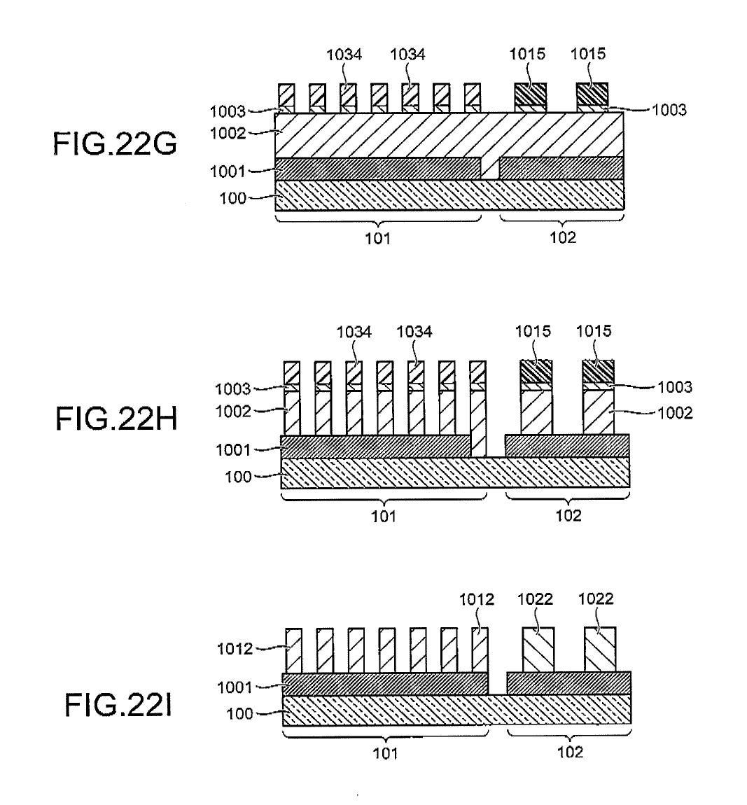

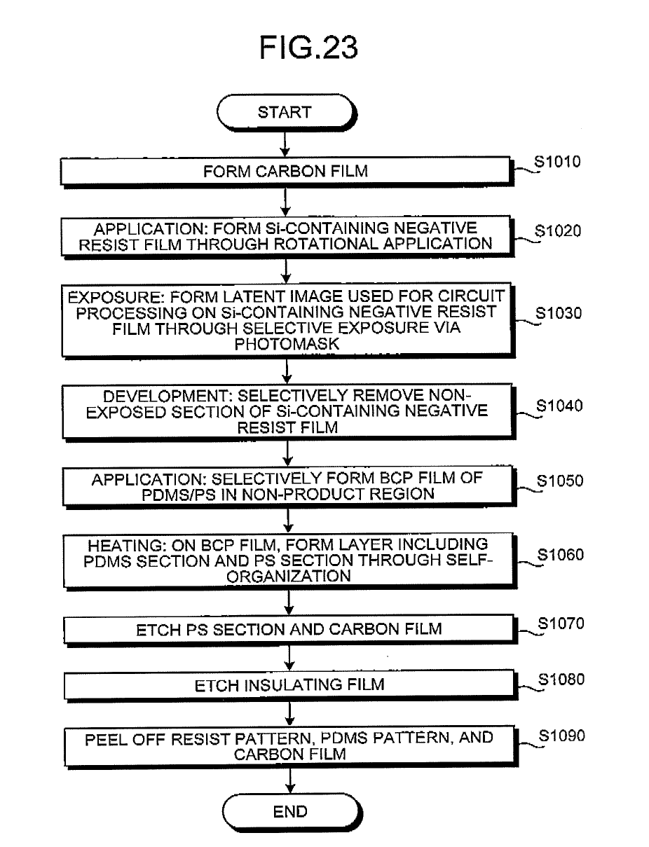

FIGS. 22A to 22I are schematic sectional views of a pattern forming process in a wire forming method according to the eighth embodiment. FIG. 23 is a flowchart for explaining a flow of the pattern forming process in the wire forming method according to the eighth embodiment.

First, the substrate to be processed 100 having a lower layer wire 1001 provided on one surface and a silicon oxide film formed on the lower layer wire 1001 as an insulating film 1002, which is a film to be processed, is prepared. A carbon film 1003 is formed on the insulating film 1002 of the substrate to be processed 100 by rotational application (step S1010 in FIG. 22A). A first film 1004 is applied on the carbon film 1003 by a rotational application method (step S1020 in FIG. 22B). A silicon-containing photosensitive material film is used for the first film 1004. In this embodiment, a negative silicon-containing resist film is used.

Subsequently, an exposing step for forming a latent image in the product region 101 of the first film 1004 is performed. The formation of the latent image is performed by transferring latent images 1014 used for circuit processing onto the first film 1004 by selective exposure for the first film 1004 via a photomask (step S1030 in FIG. 22C). A latent image is not formed on the first film 1004 on the non-product region 102. The latent image forming section becomes an insoluble layer 1024 by the selective exposure.

A developing step is performed by using the development liquid. Because the first film 1004 is a negative resist film, a region other than the latent image forming sections (the insoluble layers 1024) is selectively resolved in the development liquid and resist patterns 1034 are formed as patterns for circuit processing (step S1040 in FIG. 22D). The resist film in the non-product region 102 where latent image formation is not performed is also removed by the development liquid.

A self-assembled pattern is formed in the non-product region 102 by using a block copolymer. First, a second film 1005 is applied on the carbon film 1003 in the non-product region 102, where the first film 1004 is removed, by a selective application method and dried (step S1050 in FIG. 22E). A block copolymer (BCP) film is used for the second film 1005. In this embodiment, a block copolymer film including polydimethyl siloxane (PDMS) sections 1015 and polystyrene (PS) sections 1025 is used as the block copolymer film. The selective film formation is performed by squeeze processing for spreading an applied film with a spatula.

A ratio of each block polymer of the block copolymer (BCP) film can be adjusted according to coverage of a pattern in the product region 101. Compositions of the block copolymers are determined such that a weight fraction of the block polymers to be removed after self-assembly is larger as the coverage of the pattern in the product region 101 is smaller. Further, compositions of the block copolymers are determined such that a weight fraction of the block polymers to be removed after self-assembly is smaller as the coverage of the pattern in the product region 101 is larger.

For example, when the coverage of the pattern in the product region 101 is about 50%, a block copolymer in which a weight fraction of polydimethyl siloxane (PDMS) is set to 0.50 same as the coverage in the product region 101 is used. A self-assembled structure obtained from the block copolymers can be controlled by adjusting self-assembly temperature. For example, in the case of a diblock copolymer film formed by polydimethyl siloxane (PDMS) and polystyrene (PS), the diblock copolymer film can be formed as a lamellar structure of vertical orientation by adjusting self-assembly temperature.

Subsequently, at least the substrate peripheral edge region 102a is heated to advance self-assembly in the second film 1005. Consequently, the block copolymer film is divided into the polydimethyl siloxane (PDMS) sections 1015 and the polystyrene (PS) sections 1025 and a lamellar structure in which the polydimethyl siloxane (PDMS) sections 1015 and the polystyrene (PS) sections 1025 are upright with respect to the in-plane direction of the substrate to be processed 100 is formed (step S1060 in FIG. 22F).

Anisotropic etching of the polystyrene (PS) sections 1025 and the carbon film 1003 is performed. The etching is performed by the RIE by using oxygen gas. In the product region 101, the exposed carbon film 1003 is etched and removed. In the non-product region 102, the polystyrene (PS) sections 1025 of the second film 1005 are selectively etched and the remaining polydimethyl siloxane (PDMS) sections 1015 are formed as patterns. The exposed carbon film 1003 is etched and removed with the patterns of the polydimethyl siloxane (PDMS) sections 1015 as masks (step S1070 in FIG. 22G).

Anisotropic etching of the insulating film 1002 is performed. The etching is performed by the RIE using fluorocarbon gas (step S1080 in FIG. 22H).

The resist patterns 1034 used as the masks for circuit processing and the polydimethyl siloxane (PDMS) sections 1015 are removed by ashing and the carbon film 1003 is removed to form patterns of the insulating film 1002 (step S1090 in FIG. 22I). As the patterns of the insulating film 1002, insulating film patterns 1012 formed in the product region 101 and insulating film patterns 1022 formed in the non-product region 102 are formed. Thereafter, after barrier metal films are formed on the surfaces of the patterns of the insulating film 1002, barrier metal at the bottom is removed, metal is buried on the bottom, and a wire material formed on the outside of a wire region is abraded and removed by the CMP, whereby patterns functioning as wires can be formed.

As explained above, in the eighth embodiment, regardless of the fact that the exposure for processing pattern formation is applied to only the first film 1004 on the product region 101, the insulating film 1002 can be processed at high accuracy for both the shape of a processed pattern and a processing dimension. Consequently, at a processing stage of the insulating film 1002, processing of the insulating film 1002 is performed in the non-product region 502 with the patterns of the polydimethyl siloxane (PDMS) sections 1015 as masks. Therefore, in the product region 501 positioned near the boundary 503 between the product region 501 and the non-product region, an appropriate amount of etchant is supplied and consumed as in the product region 501 on the inner side of the substrate to be processed 100 (the product region 501 not adjacent to the non-product region 502). Therefore, the insulating film 1002 can be processed at high accuracy for both the shape of a processed pattern and a processing dimension.

In the eighth embodiment, patterning using self-assembly of the block copolymer is applied to the substrate peripheral edge region 102a, so that usage of the exposing apparatus can be reduced compared with usage of the exposing apparatus that performs peripheral exposure as in the past and productivity and cost of the exposing apparatus can be improved.

In the explanation of this embodiment, the negative silicon-containing resist is used as the first film 1004. However, a chemically amplified type resist can also be used.

In this embodiment, after the pattern for circuit processing is formed in the product region 101 by the exposure using the negative silicon-containing resist, the self-assembled pattern is formed in the non-product region 102 by the self-assembly of the block copolymer film. However, this embodiment is not limited to this. As a modification of this embodiment, it is also possible that, after the self-assembled pattern is formed in the non-product region 102 by the self-assembly of the block copolymer film, the silicon-containing resist is applied on the product region 101 and the non-product region 102 and the pattern for circuit processing is formed on the product region 101 by exposure.

In this embodiment, the wafer for semiconductor manufacturing is the substrate to be processed 100. However, various applications are possible as long as the applications are for the same pattern processing for, for example, in processing of mask blanks, applying a resist to a pattern area, exposing and developing the resist to form a resist pattern, selectively applying a block copolymer to a peripheral edge of the pattern area, and performing light blocking film and substrate processing with a self-assembled pattern as a mask.

In this embodiment, the material formed by polydimethyl siloxane (PDMS) and polystyrene (PS) is used as the block copolymer material. However, it is possible to use a material in which siloxane is mixed into the material formed by polystyrene (PS) and polymethyl methacrylate (PMMA). The mixed siloxane is selectively captured into polymethyl methacrylate (PMMA) in the block copolymer film forming stage, so that the effects same as polydimethyl siloxane (PDMS) can be obtained. Compared to the second embodiment in which the block copolymer of polystyrene (PS) and polymethyl methacrylate (PMMA) in which both of the polymers are formed by organic matter, in this embodiment in which the block copolymer of polystyrene (PS) formed by organic matter and polydimethyl siloxane (PDMS) in which silicon is included in one polymer group, one polymer block can be easily removed, which is desirable.

Therefore, according to the eighth embodiment, it is possible to efficiently form a pattern for circuit processing and perform circuit processing at high accuracy for both the shape of a processing pattern and a processing dimension using the pattern for circuit processing.

### Ninth Embodiment

In the ninth embodiment, a method of manufacturing a semiconductor device using DSA, which is an embodiment concerning Via plug formation for a lower layer wire, is explained. In this embodiment, a block copolymer (BCP) formed by polydimethyl siloxane (PDMS) and polystyrene (PS) is selectively applied to a non-product region in a semiconductor substrate. A processing error in an etching process for a product region can be reduced by self-assembled the block copolymer and selectively removing a PS section. A pattern forming method that can adjust pattern coverage, of the non-product region to be substantially the same as circuit pattern coverage without using exposure is explained below.

In the ninth embodiment, as in the first embodiment, Via plugs are formed on the substrate to be processed 100 shown in FIG. 1. It is assumed that Via plugs are formed only in the product regions 101 without being formed in the non-product region 102. In the following explanation, the non-product region 102 is the substrate peripheral edge region 102a.

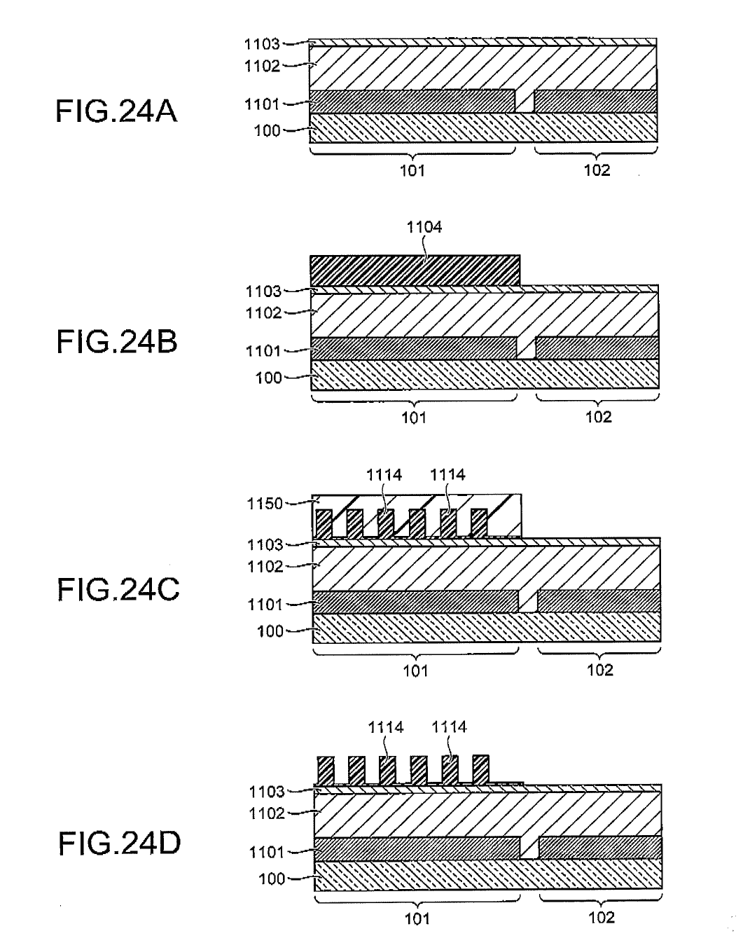

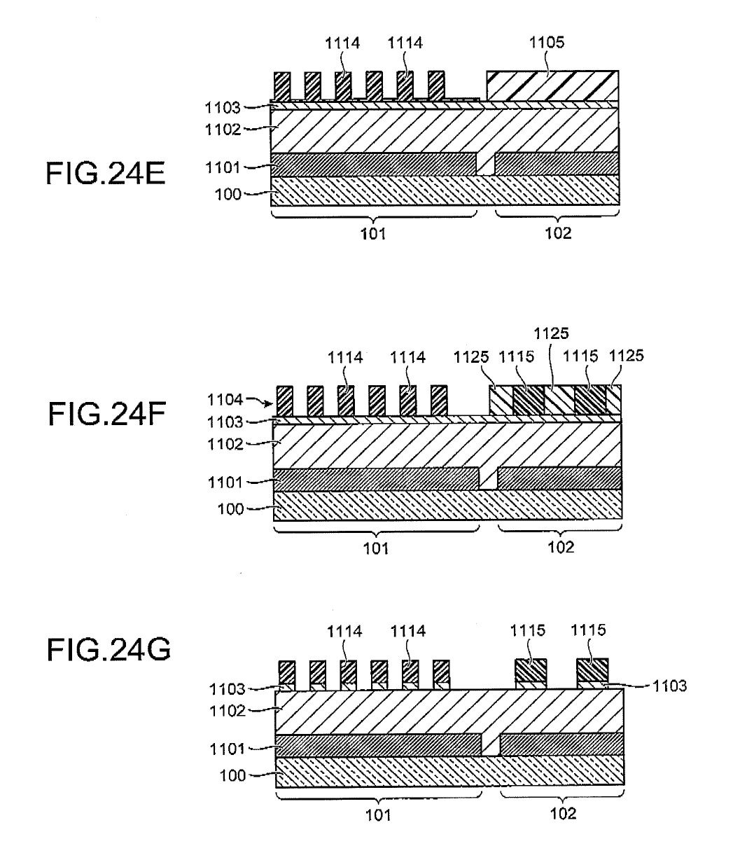

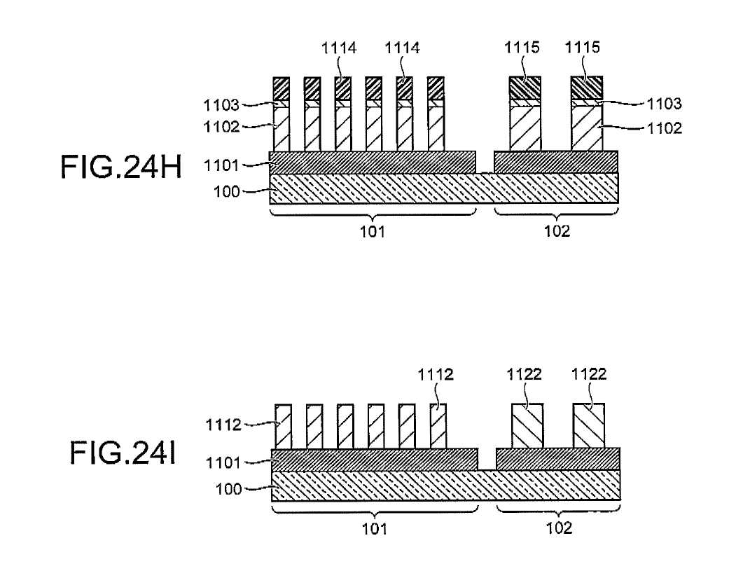

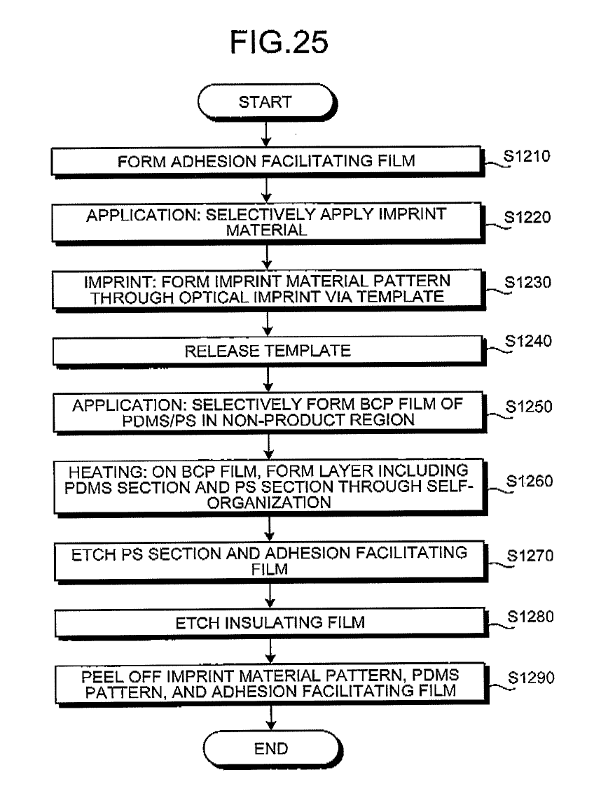

FIGS. 24A to 24I are schematic sectional views of a pattern forming process in a Via plug forming method according to the ninth embodiment. FIG. 25 is a flowchart for explaining a flow of the pattern forming process in the Via plug forming method according to the ninth embodiment.

First, the substrate to be processed 100 having a lower layer wire 1101 provided on one surface and a silicon oxide film formed on the lower layer wire 1101 as an insulating film 1102, which is a film to be processed, is prepared. An adhesion facilitating film 1103 for pattern transfer is formed on the insulating film 1102 of the substrate to be processed 100 by rotational application (step S1210 in FIG. 24A). An imprint material 1104 is selectively applied to the product region 101 on the adhesion facilitating film 1103 by an ink-jet method (step S1220 in FIG. 24B). In this embodiment, a silicon-containing photo-curing agent is used as the imprint material 1104.

Subsequently, a photo-transmissive template 1150 inscribed with a pattern for circuit processing is pressed against the imprint material 1104 to spread the imprint material 1104 and fill the imprint material 1104 in a notch of the template 1150. Light is radiated on the imprint material 1104 via the template 1150, whereby the imprint material 1104 is photo-cured (a first film) and imprint material patterns 1114 formed of the cured imprint material are formed (step S1230 in FIG. 24C). Thereafter, the template 1150 is released (step S1240 in FIG. 24D).

A self-assembled pattern is formed in the non-product region 102 using a block copolymer. First, a second film 1105 is applied on the adhesion facilitating film 1103 in the non-product region 102 by a selective application method and dried (step S1250 in FIG. 24E). A block copolymer (BCP) film is used for the second film 1105. In this embodiment, a block copolymer film including polydimethyl siloxane (PDMS) sections 1115 and polystyrene (PS) sections 1125 is used as the block copolymer film. The selective film formation is performed by squeeze processing for spreading an applied film, for example, with a spatula.

A ratio of each block polymer of the block copolymer (BCP) film can be adjusted according to coverage of a pattern in the product region 101. Compositions of the block copolymers are determined such that a weight fraction of the block polymers to be removed after self-assembly is larger as the coverage of the pattern in the product region 101 is smaller. Further, compositions of the block copolymers are determined such that a weight fraction of the block polymers to be removed after self-assembly is smaller as the coverage of the pattern in the product region 101 is larger.

For example, when the coverage of the pattern in the product region 101 is about 80%, a block copolymer in which a weight fraction of polydimethyl siloxane (PDMS) is set to 0.80 same as the coverage in the product region 101 is used. A self-assembled structure obtained from the block copolymers can be controlled by adjusting self-assembly temperature. For example, in the case of a diblock copolymer film formed by polydimethyl siloxane (PDMS) and polystyrene (PS), by adjusting the self-assembled temperature, the diblock copolymer film can be formed as a self-assembled structure in which polydimethyl siloxane (PDMS) surrounds columnar polystyrene (PS).

Subsequently, at least the substrate peripheral edge region 102a is heated to advance self-assembly in the second film 1105. Consequently, the block copolymer film is divided into the polydimethyl siloxane (PDMS) sections 1115 and the polystyrene (PS) sections 1125 (step S1260 in FIG. 24F). A structure in which the polystyrene (PS) sections 1125 are columnar structures upright with respect to the in-plane direction of the substrate to be processed 100 and the polydimethyl siloxane (PDMS) sections 1115 are upright with respect to the in-plane direction of the substrate to be processed 100 to surround the columnar structures is formed.

Subsequently, because a thin film of a silicon-containing photo-curing agent is present in a nanoimprint region, for removing this film, first, etching is performed by the RIE by using fluorocarbon gas and oxygen gas. Subsequently, anisotropic etching of the polystyrene (PS) sections 1125 and the adhesion facilitating film 1103 is performed using only oxygen gas. In the product region 101, the exposed adhesion facilitating film 1103 is etched and removed. In the non-product region 102, the polystyrene (PS) sections 1125 of the second film 1105 are selectively etched and the remaining polydimethyl siloxane (PDMS) sections 1115 are formed as patterns. The exposed adhesion facilitating film 1103 is etched and removed with the polydimethyl siloxane (PDMS) sections 1115 as masks (step S1270 in FIG. 24G).

Anisotropic etching of the insulating film 1102 is performed. The etching is performed by the RIE using fluorocarbon gas (step S1280 in FIG. 24H). In this process, the silicon-containing photo-curing film on the carbon film and siloxane components of polydimethyl siloxane (PDMS) are also removed and residue of the adhesion facilitating film remains.

The imprint material patterns 1114 used as the masks for circuit processing, the polydimethyl siloxane (PDMS) sections 1115, and the adhesion facilitating film 1103 are removed by ashing to form patterns of the insulating film 1102 (step S1290 in FIG. 24I). As the patterns of the insulating film 1102, insulating film patterns 1112 formed in the product region 101 and insulating film patterns 1122 formed in the non-product region 102 are formed. Thereafter, after barrier metal films are formed on the surfaces of the patterns of the insulating film 1102, barrier metal at the bottom is removed, metal is buried on the bottom, and a Via material formed on the outside of a Via region is abraded and removed by the CMP, whereby patterns functioning as Via plugs can be formed.

As explained above, in the ninth embodiment, regardless of the fact that the imprint for processing pattern formation is applied to only the product region 101, the insulating film 1102 can be processed at high accuracy for both the shape of a processed pattern and a processing dimension. Consequently, at a processing stage of the insulating film 1102, processing of the insulating film 1102 is performed in the non-product region 102 with the patterns of the polydimethyl siloxane (PDMS) sections 1115 as masks. Therefore, in the peripheral edge region of the product region 101, an appropriate amount of etchant is supplied and consumed as in the product region 101 on the inner side of the substrate to be processed 100 (the product region 101 not adjacent to the non-product region 102). Therefore, the insulating film 1102 can be processed at high accuracy for both the shape of a processed pattern and a processing dimension.

In this embodiment, the imprint is performed by optical imprint. However, thermal imprint for curing the imprint material with heat using thermally crosslinked siloxane material can also be used.

In this embodiment, the material formed by polydimethyl siloxane (PDMS) and polystyrene (PS) is used as the block copolymer material. However, it is possible to use a material in which siloxane is mixed into the material formed by polystyrene (PS) and polymethyl methacrylate (PMMA). The mixed siloxane is selectively captured into polymethyl methacrylate (PMMA) in the block copolymer film forming stage, so that the effects same as polydimethyl siloxane (PDMS) can be obtained. Compared to the second embodiment in which the block copolymer of polystyrene (PS) and polymethyl methacrylate (PMMA) in which both of the polymers are formed by organic matter, in this embodiment in which the block copolymer of polystyrene (PS) formed by organic matter and polydimethyl siloxane (PDMS) in which silicon is included in one polymer group, one polymer block can be easily removed, which is desirable.

Therefore, according to the ninth embodiment, it is possible to efficiently form a pattern for circuit processing and perform circuit processing at high accuracy for both the shape of a processing pattern and a processing dimension using the pattern for circuit processing.

In the eighth embodiment, as exposing means used for the selective exposure for the first film via the photomask, it is possible to use reduced projection exposure, equal magnification exposure, or the like performed via a photomask corresponding to a circuit formation purpose using radiation such as an i ray, a g ray, KrF, ArF, or EUV as a light source. Instead of the selective exposure via the photomask, exposure can also be performed by charged particle radiation such as selective electron beam radiation by an electron beam.

In the explanation of the eighth and ninth embodiments, the diblock copolymer formed of the polydimethyl siloxane (PDMS) sections and the polystyrene (PS) sections is used as the block copolymer used for the second film. However, the block copolymer is not limited to this. Any material can be used as long as a processing resistive material having resistance against processing of a film to be processed is included in one copolymer or a processing resistant substance is captured into one copolymer side during self-assembly. In other words, as the second film, a block copolymer containing film containing such block copolymer can be used.

For example, in etching using oxygen or fluorocarbon gas, a coverage adjusted pattern formed of a polymer group including a benzene ring can be formed by using a polymer mixed film obtained by mixing a polymer including the benzene ring and a polymer not including the benzene ring and selectively removing a polymer group not including the benzene ring in the etching process after the DSA. As another example, in etching using fluorine gas, a coverage adjusted pattern formed by an organic polymer section with siloxane polymer removed can be formed by using a polymer mixed film formed of a material obtained by mixing organic polymer and the siloxane polymer.

In the first to ninth embodiments, as exposing means used for the selective exposure for the first film via the photomask, it is possible to use reduced projection exposure, equal magnification exposure, or the like performed via a photomask corresponding to a circuit formation purpose using radiation such as an i ray, a g ray, KrF, ArF, or EUV as a light source. Instead of the selective exposure via the photomask, exposure can also be performed by charged particle radiation such as selective electron beam radiation by an electron beam.

In the explanation of the first to ninth embodiments, the film to be processed as the processing target is the silicon oxide film. However, the film to be processed is not limited to this. As the film to be processed as the processing target, materials required to be processed for circuit manufacturing such as amorphous silicon, a silicon nitride film, a wiring material, and an electrode material can be also be used. The width of the self-assembled structure only has to be in a range from width equal to a circuit processing target dimension to width about 500 times as large as the circuit processing target dimension as long as predetermined coverage is satisfied.

In the first to ninth embodiments, the heating for causing the polymer mixed film to perform the self-assembly can be selected as appropriate according to process specification such as (1) heating of the entire substrate to be processed, (2) selective heating for an application region of the polymer mixed film by a lamp or the like, and (3) concurrent use of the heating (2) and other temperature adjustment.

In the first to ninth embodiments, when the block copolymer or the polymer mixed film can take the lamellar structure or the co-continuous structure through the self-assembly, it is desirable to form the block copolymer or the polymer mixed film in the lamellar structure by controlling temperature or pressure for the self-assembly. The lamellar structure is desirable as a processing mask in etching a film to be processed because an irregularity state is more clearly distinguished in the lamellar structure than in the co-continuous structure. When the block copolymer or the polymer mixed film can take the columnar structure or the spherical structure through the self-assembly, it is desirable to form the block copolymer or the polymer mixed film in the columnar structure by controlling temperature or pressure for the self-assembly. The columnar structure is desirable as a processing mask in etching a film to be processed because an irregularity state is more clearly distinguished in the columnar structure than in the spherical structure.

In the first to ninth embodiments, it is desirable to perform pattern formation for the non-product region 102 using a block copolymer or a polymer mixed film having a weight fraction corresponding to pattern coverage in the product region 101. For example, when the pattern coverage of the product region 101 is “a”, it is ideal to use a polymer, a weight fraction of which being selectively left in base processing is “a”, i.e., a polymer, a weight fraction of which being removed after the self-assembly is 1-a. It was confirmed in an experiment performed by changing a weight fraction that the object of this embodiment could be attained when a weight fraction of a polymer was in a range of +/−20% with reference to “a”. In the explanation of the embodiments, the two kinds of polymers are used. However, it is possible to apply to a block copolymer or a polymer mixed film formed of two or more kinds of polymers.

For example, when a wiring pattern (having coverage of about 50%) of a cell is formed in a product region of a NAND memory or the like, it is desirable to adjust a weight fraction of each polymer of a polymer mixed film and form the polymer mixed film in the lamellar structure having coverage of about 50%. When a pattern of a circuit region has a purpose of processing a base with pillars (isolated projections) as masks, because coverage is equal to or lower than 10%, it is desirable to form a section to be a mask for base processing in the spherical structure as a self-assembled structure of a polymer in a non-circuit region. In this way, it is desirable to design polymer compositions of each polymer (degrees of polymerization) according to coverage of a product circuit region such that a weight fraction of the polymer to be the mask for the base processing generally coincides with the coverage of the product circuit region and use a manufactured block copolymer or polymer mixed film. When the self-assembled structure is columnar structure or spherical structure, the self-assembled structure can be used not only in upright structure but also in arrangement such as parallel arrangement or floating arrangement.

In the first to ninth embodiments, the self-assembly of the block copolymer is performed by heating. However, the self-assembly of the block copolymer can also be performed in a pressed state of an entire substrate.

As explained above, it is also possible to evaluate, as the non-product region 102, not only the chipped shot region 504 (see FIG. 8) of the substrate peripheral edge not functioning as a device even if exposure is performed to form a circuit but also a chip region (the defective region 102b) on the inside of the substrate failing to function as a device because of a process failure or the like and apply this embodiment to the regions (see FIG. 1).

### Tenth Embodiment

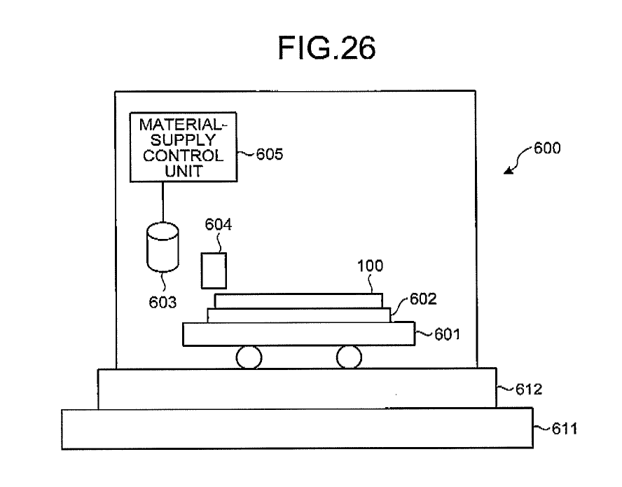

In the tenth embodiment, an example of a pattern forming apparatus that realizes pattern formation using the block copolymer material or the polymer mixed material in the first to ninth embodiments is explained. In this embodiment, explanation is given for an example of using the block copolymer material. However, the polymer mixed material can also be used instead thereof. FIG. 26 is a diagram of a schematic configuration of a pattern forming apparatus 600. The pattern forming apparatus 600 includes a stage for substrate to be processed 601, a substrate-to-be-processed chuck 602, a material supplying unit 603, a leveling unit 604, a material-supply control unit 605, and a not-shown self-assembled unit.

The substrate-to-be-processed chuck 602 is a substrate-to-be-processed holding unit that fixes and holds a wafer that is the substrate to be processed 100. The stage for substrate to be processed 601 is a substrate-to-be-processed moving unit on which the substrate-to-be-processed chuck 602 is placed and two-dimensionally moved in the horizontal direction, whereby the substrate to be processed 100 is two-dimensionally moved in the horizontal direction. The material supplying unit 603 selectively supplies a block copolymer material to the non-product region 102 on the substrate to be processed 100. The leveling unit 604 presses the applied block copolymer material and spreads the block copolymer material over the substrate to be processed 100. In some case, the leveling unit 604 is combined to the material supplying unit 603. The material-supply control unit 605 controls a material supply position and a material supply amount by the material supplying unit 603. The material-supply control unit 605 controls the supply position and the supply amount such that desired film thickness and thickness uniformity are obtained when the material supplied from the material supplying unit 603 is leveled. In some case, the pattern forming apparatus 600 is used while being placed on a stage plate 612 placed on a vibration removing table 611.

The material supplying unit 603 is controlled to supply the block copolymer material onto the substrate to be processed 100 with, for example, an ink-jet method and supply a desired amount of the material to a predetermined position on the substrate to be processed 100 according to a command from the material-supply control unit 605. When the material supplying unit 603 supplies the material to the non-product region 102, the material-supply control unit 605 determines a position of the material supply according to, for example, forms explained below.

(1) The material-supply control unit 605 discriminates the non-product region 102 from an observed image of the substrate to be processed 100 to determine the position.
(2) The material-supply control unit 605 discriminates the product region 101 and the non-product region 102 referring to an exposure map, substrate shot information, and the like to determine a material supply region.

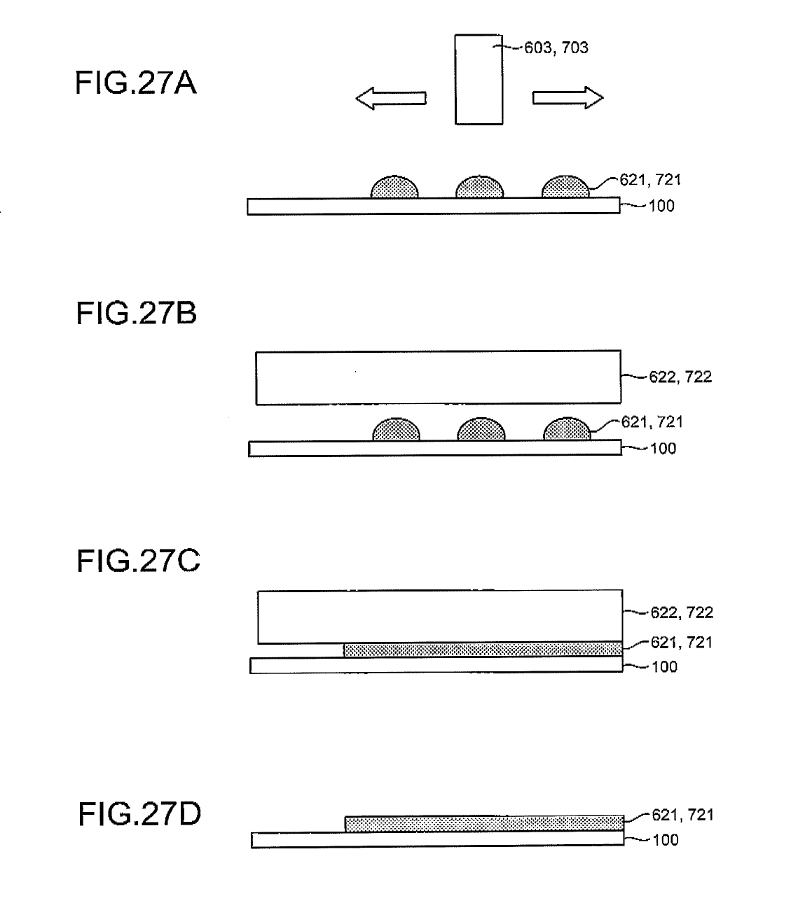

The material-supply control unit 605 determines a material supply amount taking into account irregularities, an edge position, and the like of the substrate to be processed 100 such that a material film is formed in desired thickness in leveling processing performed after the material supply. FIGS. 27A to 27D are schematic sectional views of a method of applying a block copolymer material by the pattern forming apparatus 600. To selectively apply the block copolymer material with the pattern forming apparatus 600, first, a block copolymer material 621 is intermittently dropped onto the substrate to be processed 100 from an ejection nozzle (not shown) of the material supplying unit 603 by the ink-jet method while the substrate to be processed 100 and the material supplying unit 603 are relatively moved (FIG. 27A).

Subsequently, leveling processing is performed. Specifically, a flat plate 622, which is the leveling unit 604, is arranged on the block copolymer material 621, which is intermittently dropped onto the substrate to be processed 100, substantially parallel to the in-plane direction of the substrate to be processed 100 (FIG. 27B). The flat plate 622 is pressed against the block copolymer material 621 (FIG. 27C). Finally, the flat plate 622 is separated from the block copolymer material 621 (FIG. 27D).

When the block copolymer material is dropped from the material supplying unit 603 onto the substrate to be processed 100 by the ink-jet method, it is difficult to uniformalize a surface state of the block copolymer material 621. However, by carrying out the leveling processing as explained above, it is possible to substantially uniformalize a surface state of the block copolymer material 621 formed as a film.

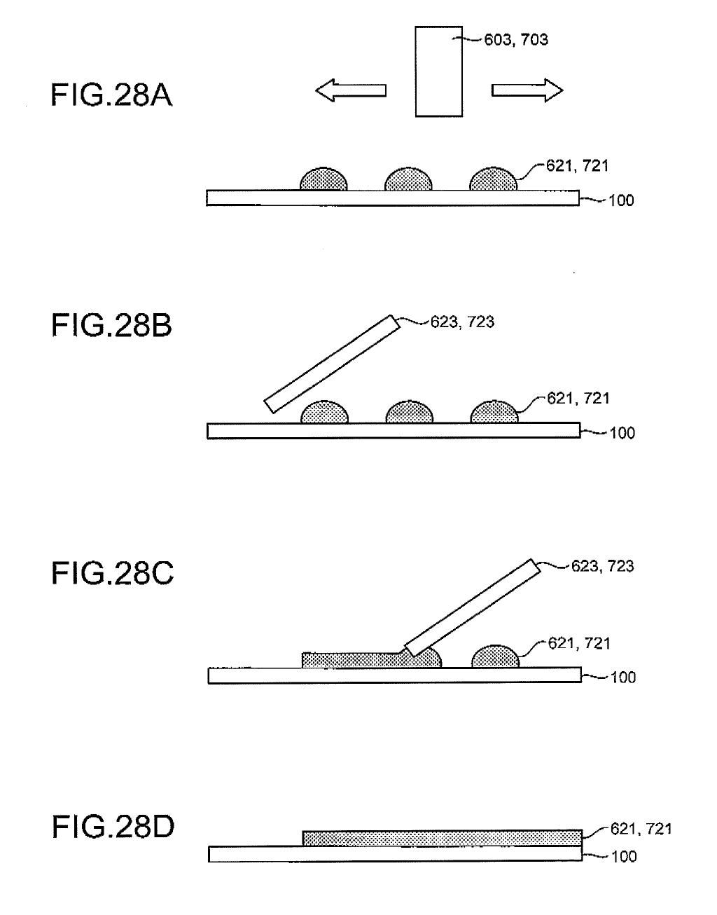

FIGS. 28A to 28D are schematic sectional views of another method of applying the block copolymer material by the pattern forming apparatus 600. As another example of the method of applying the block copolymer material by the pattern forming apparatus 600, the block copolymer material 621 is intermittently dropped onto the substrate to be processed 100 from the ejection nozzle (not shown) of the material supplying unit 603 while the substrate to be processed 100 and the material supplying unit 603 are relatively moved (FIG. 28A).

Subsequently, leveling processing is performed. Specifically, a squeeze plate 623, which is the leveling unit 604, is arranged on the block copolymer material 621, which is intermittently dropped onto the substrate to be processed 100, at a predetermined angle with respect to the in-plane direction of the substrate to be processed 100 (FIG. 28B). The squeeze plate 623 is moved in the horizontal direction while being pressed against the block copolymer material 621 (FIG. 28C). Finally, the squeeze plate 623 is separated from the block copolymer material 621 (FIG. 28D).

As another example of the method of applying the block copolymer material by the squeeze method to the non-product region 102, it is possible that a nozzle provided with a slit is used, a block copolymer material 721 is supplied while moving the slit, and further a supplied liquid is squeezed by a nozzle inner wall to supply the block copolymer material 721 on the surface. When the liquid film supplied on the surface is thicker than a desired value, excess liquid film can be suctioned and removed by the nozzle provided with the slit.

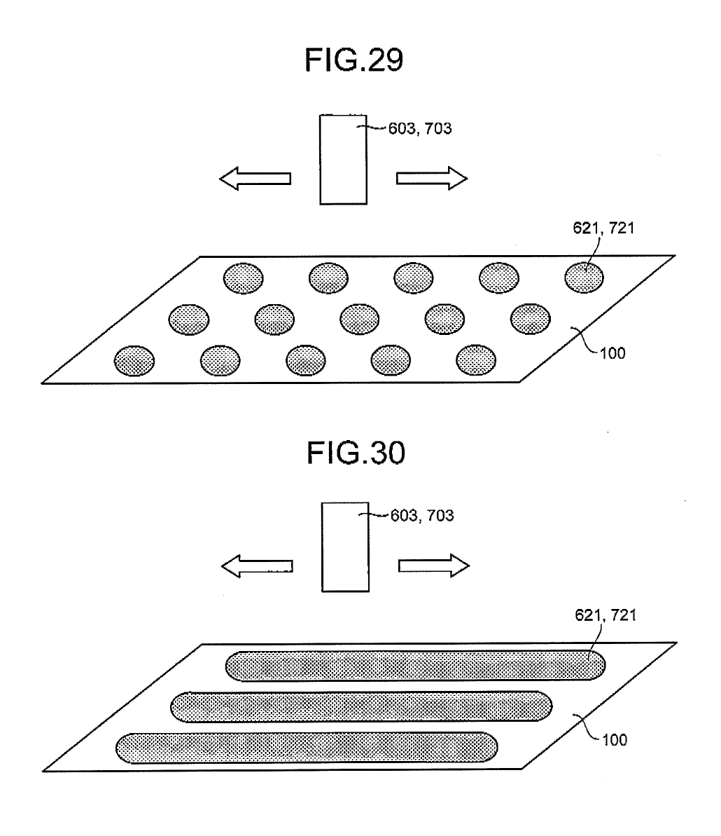

FIGS. 29 and 30 are schematic diagrams of an example of a supply state of the block copolymer material 621 on the substrate to be processed 100 by the pattern forming apparatus 600. The block copolymer material 621 supplied onto the substrate to be processed 100 can be an intermittent dot shape as shown in FIG. 29 or can be a plurality of continuous linear shapes as shown in FIG. 30. The block copolymer material 621 can be supplied in any shape as long as desired thickness is obtained in a material film after the leveling processing.

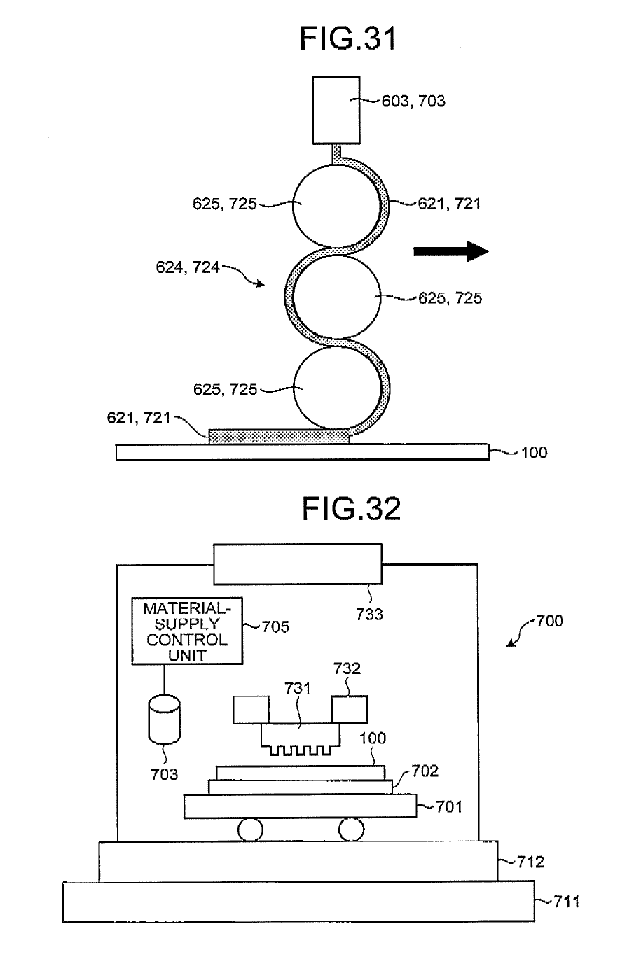

FIG. 31 is a schematic sectional view of another example of the method of supplying the block copolymer material 621 onto the substrate to be processed 100 by the pattern forming apparatus 600. As another form of the method of supplying the block copolymer material 621 onto the substrate to be processed 100, first, a multi-stage roller 624 obtained by placing rollers 625 one on top of another in substantially the vertical direction in three stages is arranged spaced apart from the substrate to be processed 100. Subsequently, the block copolymer material 621 is supplied onto the roller 625 at the upper stage from the material supplying unit 603. The rollers 625 are rotated in opposite directions from one another and the multi-stage roller 624 is moved in the horizontal direction. This makes it possible to form a film of the block copolymer material 621 at desired thickness and in a desired shape while spreading the block copolymer material 621 over the substrate to be processed 100. The number of stages and the arrangement of rollers can be appropriately changed so that required film thickness uniformity and applying profile can be realized.

Self-assembly of the block copolymer material 621 applied on the substrate to be processed 100 by the pattern forming apparatus 600 is performed by, after applying the block copolymer material 621 on the substrate to be processed 100 and drying the block copolymer material 621, conveying, with a not-shown conveying system, the substrate to be processed 100 to the self-assembled unit having a heating function and heating the substrate to be processed 100. As another form of the self-assembled unit, the self-assembled unit has a pressing function. The self-assembly of the block copolymer material 621 can also be performed by pressing the substrate to be processed 100. Further, as another form of the self-assembled unit, the self-assembled unit has the heating function and the pressing function. And in some case, the self-assembled unit has the supplying function of solvent atmosphere. The self-assembly of the block copolymer material 621 can also be performed by simultaneously performing heating and pressing. In this case, self-assembled speed can be increased. The self-assembled unit can also be provided separately.

Therefore, with the pattern forming apparatus 600, it is possible to efficiently form a pattern for circuit processing. It is possible to perform circuit processing at high accuracy for both the shape of a processing pattern and a processing dimension using the pattern for circuit processing.

Another example of the pattern forming apparatus that realizes pattern formation using the block copolymer material or the polymer mixed material in the pattern forming method is explained taking the case of using the block copolymer material as an example. FIG. 32 is a diagram of a schematic configuration of a pattern forming apparatus 700. The pattern forming apparatus 700 includes a stage for substrate to be processed 701, a substrate-to-be-processed chuck 702, a material supplying unit 703, a leveling unit (not shown), a material-supply control unit 705, a template for imprint 731, a template holding unit 732, a template compression-bonding unit (not shown), an imprint-material curing unit 733, and a not-shown self-assembled unit.

The substrate-to-be-processed chuck 702 is a substrate-to-be-processed holding unit that fixes and holds a wafer that is the substrate to be processed 100. The stage for substrate to be processed 701 is a substrate-to-be-processed moving unit on which the substrate-to-be-processed chuck 702 is placed and two-dimensionally moved in the horizontal direction, whereby the substrate to be processed 100 is two-dimensionally moved in the horizontal direction. The material supplying unit 703 selectively supplies application liquid onto the substrate to be processed 100. The leveling unit presses the material supplied onto the substrate to be processed 100 and spreads the material over the substrate to be processed 100. The material-supply control unit 705 controls a material supply position and a material supply amount by the material supplying unit 703. The material-supply control unit 705 controls, based on information concerning the product region 101 where a product is acquired and the non-product region 102 where a product is not acquired in the substrate to be processed 100, the material supplying unit 703 to selectively supply predetermined application liquid onto the substrate to be processed 100. The material-supply control unit 705 can acquire these kinds of information from the outside. The material-supply control unit 705 itself can also include means for generating these kinds of information. The material-supply control unit 705 controls the supply position and the supply amount such that desired film thickness and thickness uniformity are obtained when the material supplied from the material supplying unit 703 is leveled.

A molding pattern (a circuit pattern) is inscribed on the template 731. The template holding unit 732 fixes and holds the template for imprint 731. The template compression-bonding unit (not shown) moves the template holding unit 732 to thereby bring the molding pattern into contact with an imprint material and compression-bonds the template for imprint 731 to a material of the substrate to be processed 100 or separates the template for imprint 731 from the material. The imprint-material curing unit 733 cures an imprint material for imprint. In some case, the pattern forming apparatus 700 is used while being placed on a stage plate 712 placed on a vibration removing table 711.

The material supplying unit 703 supplies the application liquid onto the substrate to be processed 100 with, for example, the ink-jet method. The material supplying unit 703 is controlled to supply a desired amount of the material to a predetermined position on the substrate to be processed 100 while selecting the application liquid according to a command from the material-supply control unit 705. The material supplying unit 703 selects an imprint material and supplies the imprint material to the product region 101. On the other hand, the material supplying unit 703 selects a block copolymer material and supplies the block copolymer material to the non-product region 102. When the material supplying unit 703 performs material supply, the material-supply control unit 705 determines a position of the material supply according to, for example, forms explained below.

(1) The material-supply control unit 705 discriminates the product region 101 and the non-product region 102 from an observed image of the substrate to be processed 100 to determine the position.
(2) The material-supply control unit 705 discriminates the product region 101 and the non-product region 102 referring to an exposure map, substrate shot information, and the like to determine a material supply region.

The material-supply control unit 705 determines a material supply amount taking into account irregularities, an edge position, and the like of the substrate to be processed 100 such that a material film is formed in desired thickness in leveling processing performed after the material supply. The material-supply control unit 705 determines a supply amount of the imprint material to the product region 101 taking into account pattern coverage.

As the template for imprint 731, for example, a template obtained by forming, with plasma etching, a pattern of irregularities on a totally-transparent quartz substrate used for a general photomask is used. As the imprint-material curing unit 733, for example, when optical imprint is performed, a UV lamp that performs UV radiation on an imprint material via the template for imprint 731 is used.

To selectively apply a block copolymer material to the non-product region 102 of the substrate to be processed 100 with the pattern forming apparatus 700, first, the block copolymer material 721 is intermittently, continuously (linearly), or both intermittently and continuously (linearly) dropped onto the substrate to be processed 100 from an ejection nozzle (not shown) of the material supplying unit 703 by the ink-jet method while the substrate to be processed 100 and the material supplying unit 703 are relatively moved (FIG. 27A).

Subsequently, leveling processing is performed. Specifically, a flat plate 722, which is the leveling unit, is arranged on the block copolymer material 721, which is dropped onto the substrate to be processed 100, substantially parallel to the in-plane direction of the substrate to be processed 100 (FIG. 27B). The flat plate 722 is pressed against the block copolymer material 721 (FIG. 27C). Finally, the flat plate 722 is separated from the block copolymer material 721 (FIG. 27D).

When the block copolymer material 721 is dropped from the material supplying unit 703 onto the substrate to be processed 100 by the ink-jet method, it is difficult to uniformalize a surface state of the block copolymer material 721. However, by carrying out the leveling processing as explained above, it is possible to substantially uniformalize a surface state of the block copolymer material 721 formed as a film.

As another method of applying the block copolymer material to the non-product region 102 by the pattern forming apparatus 700, first, the block copolymer material 721 is intermittently (FIG. 29), continuously (linearly) (FIG. 30), or both intermittently and continuously (linearly) dropped onto the substrate to be processed 100 from the ejection nozzle (not shown) of the material supplying unit 703 while the substrate to be processed 100 and the material supplying unit 703 are relatively moved (FIG. 28A).

Subsequently, leveling processing is performed. Specifically, a squeeze plate 723, which is the leveling unit, is arranged on the block copolymer material 721, which is intermittently dropped onto the substrate to be processed 100, at a predetermined angle with respect to the in-plane direction of the substrate to be processed 100 (FIG. 28B). The squeeze plate 723 is moved in the horizontal direction while being pressed against the block copolymer material 721 (FIG. 28C). Finally, the squeeze plate 723 is separated from the block copolymer material 721 (FIG. 28D).

As another example of the method of applying the block copolymer material by the squeeze method to the non-product region 102, it is possible that a nozzle provided with a slit is used, the block copolymer material 721 is supplied while moving the slit, and further a supplied liquid is squeezed by a nozzle inner wall to supply the block copolymer material 721 on the surface. When the liquid film supplied on the surface is thicker than a desired value, excess liquid film can be suctioned and removed by the nozzle provided with the slit.

As another example of the method of applying the block copolymer material onto the substrate to be processed 100 by the pattern forming apparatus 700, first, the block copolymer material 721 is supplied from the material supplying unit 703 onto a roller 725 at an upper stage of a multi-stage roller 724 obtained by placing rollers 725 one on top of another in substantially the vertical direction in three stages. The rollers 725 are rotated in opposite directions from one another and the multi-stage roller 724 is moved in the horizontal direction. This makes it possible to form a film of the block copolymer material 721 at desired thickness while spreading the block copolymer material 721 material film over the substrate to be processed 100. The number of stages and the arrangement of rollers can be appropriately changed so that required film thickness uniformity and applying profile can be realized.

Self-assembly of the block copolymer material 721 applied on the substrate to be processed 100 by the pattern forming apparatus 700 is performed by, after applying the block copolymer material 721 on the substrate to be processed 100 and drying the block copolymer material 721, conveying, with a not-shown conveying system, the substrate to be processed 100 to the self-assembled unit having a heating function and heating the substrate to be processed 100. As another form of the self-assembled unit, the self-assembled unit has a pressing function. The self-assembly of the block copolymer material 721 can also be performed by pressing the substrate to be processed 100. Further, as another form of the self-assembled unit, the self-assembled unit has the heating function and the pressing function. And in some case, the self-assembled unit has the supplying function of solvent atmosphere. The self-assembly of the block copolymer material 721 can also be performed by simultaneously performing heating and pressing. In this case, self-assembled speed can be increased. The self-assembled unit can also be provided separately.

Therefore, with the pattern forming apparatus 700, it is possible to efficiently form a pattern for circuit processing. It is possible to perform circuit processing at high accuracy for both the shape of a processing pattern and a processing dimension using the pattern for circuit processing.

On the other hand, a photo-curing agent can be applied to the product region 101 as an imprint material basically in the same manner as the selective application to the non-product region 102. When the imprint material is applied to the product region 101, because a larger amount of application liquid is necessary as there are a larger number recessed portion, the material-supply control unit 705 controls an application liquid supply amount to increase the supply according to an irregularity ratio of the template 731 to be impressed. This makes it possible to prevent a shape failure due to insufficiency of the imprint material and perform satisfactory imprint.

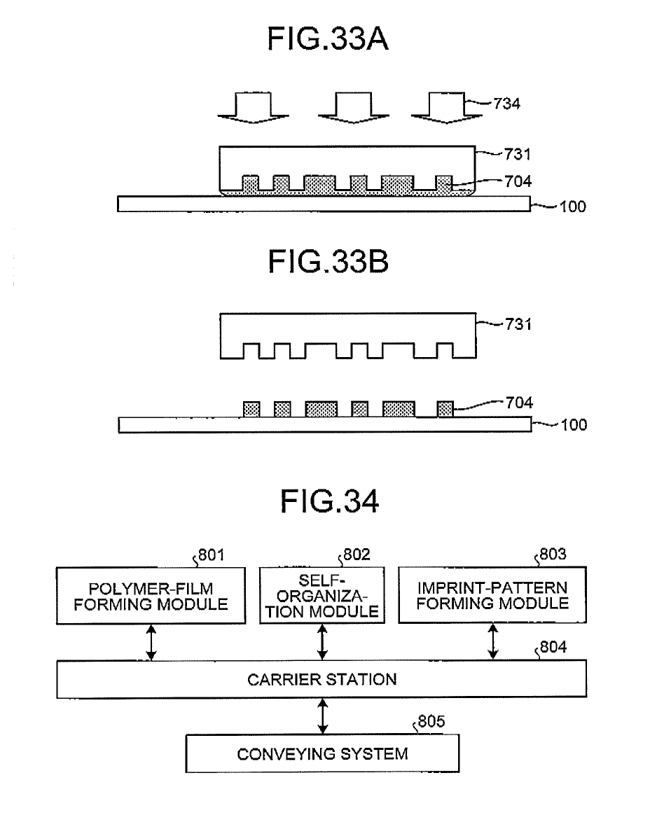

FIGS. 33A and 33B are schematic sectional views of imprint processing by the pattern forming apparatus 700. In the imprint, the template 731 is pressed against an imprint material (a photo-curing agent) 704 applied to the product region 101 to spread the imprint material (the photo-curing agent) 704 and fill the imprint material (the photo-curing agent) 704 in the irregularities of the template 731. UV radiation 734 is applied to the imprint material (the photo-curing agent) from a UV lamp as the imprint-material curing unit 733 via the template 731 (FIG. 33A). Consequently, the imprint material (the photo-curing agent) 704 is photo-cured and an imprint material pattern formed of the cured imprint material (photo-curing agent) 704 is formed. Thereafter, the template 731 is released (FIG. 33B).

In the above explanation, the imprint is performed by the optical imprint. However, if an imprint material has thermosetting properties, light radiation does not have to be performed and the imprint material only has to be heated in a state in which a template is impressed on the imprint material. A heating mechanism can also be provided in the pattern forming apparatus 700 instead of the UV lamp.

On the other hand, for example, as shown in FIG. 34, a module system can include a polymer-film forming module 801 (a plurality of which can be set) that forms a block copolymer film or a polymer mixed film, a self-assembly module 802 (a plurality of which can be set) that carries out self-assembly of the formed polymer film, an imprint-pattern forming module 803 (a plurality of which can be set) that performs imprint to form an imprint pattern, a carrier station 804 that carries a carrier, which houses the substrate to be processed 100, into an exposing device and carries out the carrier from the exposing device, and a conveying system 805 that conveys the substrate to be processed 100 among the modules and the carrier station. The product region 101 and the non-product region 102 of the substrate to be processed 100 can be processed in different modules. FIG. 34 is a diagram of an example of the module system.

For example, after a block copolymer film or a polymer mixed film is applied to the non-product region 102 of the substrate to be processed 100 by the polymer-film forming module 801, the substrate to be processed 100 is conveyed to the self-assembly module 802 by the conveying system 805. After processing for performing self-assembly of the block copolymer film and generating a dummy pattern is performed by the self-assembly module 802, the substrate to be processed 100 is conveyed to the imprint-pattern forming module 803 by the conveying system 805. Imprint patterning processing is applied to the product region 101 of the substrate to be processed 100 by the imprint-pattern forming module 803.

After the imprint patterning processing is applied to the product region 101 of the substrate to be processed 100 by the imprint-pattern forming module 803, the substrate to be processed 100 is conveyed to the polymer-film forming module 801 by the conveying system 805. After applying the block copolymer film to the non-product region 102 of the substrate to be processed 100 by the polymer-film forming module 801, the substrate to be processed 100 is conveyed to the self-assembly module 802 by the conveying system 805. The processing for performing self-assembly of the block copolymer film and generating a dummy pattern is performed by the self-assembly module 802. In this way, it is also possible to operate the module system as a system in which the modules to be used are divided for each formation purpose of a pattern.

When such a system is configured, as in the pattern forming apparatus 600 and the pattern forming apparatus 700, it is possible to efficiently form a pattern for circuit processing and perform circuit processing at high accuracy for both the shape of a processing pattern and a processing dimension using the pattern for circuit processing.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A pattern forming method for forming a first film in a first region on a film to be processed formed on a substrate to be processed and patterning the first film to thereby form a first pattern having first pattern coverage as pattern coverage and forming a second pattern having second pattern coverage as pattern coverage in a second region on the film to be processed different from the first region, the pattern forming method comprising:
in forming the second pattern,
forming a second film formed of a block copolymer containing film or a polymer mixed film on the film to be processed;
self-assembled the second film; and
selectively removing a plurality of kinds of polymers contained in the self-assembled second film to leave at least one kind of polymer to thereby form the second pattern in the second region to bring the second pattern coverage close to the first pattern coverage.

2. A pattern forming method comprising:
forming a photosensitive material film in a first region on a film to be processed formed on a substrate to be processed;
forming a block copolymer containing film or a polymer mixed film in a second region different from the first region on the film to be processed;
selectively applying exposure to the photosensitive material film;
forming a first pattern in the first region according to development of the photosensitive material film;
self-assembled the block copolymer containing film or the polymer mixed film; and
selectively removing a plurality of kinds of polymers contained in the self-assembled block copolymer containing film or polymer mixed film to leave at least one kind of polymer to thereby form a second pattern in the second region.

3. The pattern forming method according to claim 2, further comprising, after applying the block copolymer containing film or the polymer mixed film to the second region, leveling a surface of the block copolymer containing film or the polymer mixed film.

4. The pattern forming method according to claim 2, wherein
the second region is a non-product region where a product is not acquired on the substrate to be processed.

5. The pattern forming method according to claim 2, wherein, when pattern coverage of the first pattern is “a”, a block copolymer containing film or a polymer mixed film in which a weight fraction of a polymer to be removed after the self-assembly is “1-a” is used as the block copolymer containing film or the polymer mixed film.

6. The pattern forming method according to claim 2, wherein at least one kind of polymer among a plurality of kinds of polymers contained in the block copolymer containing film or the polymer mixed film has resistance against processing of the film to be processed.

7. A pattern forming method comprising:
forming a photosensitive material film over an entire surface of a film to be processed formed on a substrate to be processed;
selectively applying exposure to a first region of the photosensitive material film;
forming a first pattern in the first region according to development of the photosensitive material film and removing the photosensitive material film on a second region different from the first region;
forming a block copolymer containing film or a polymer mixed film on the second region;
self-assembled the block copolymer containing film or the polymer mixed film; and
selectively removing a plurality of kinds of polymers contained in the self-assembled block copolymer containing film or polymer mixed film to leave at least one kind of polymer to thereby form a second pattern in the second region.

8. A pattern forming method comprising:
forming, by an imprint method, a first pattern in a first region on a film to be processed formed on a substrate to be processed;
forming a block copolymer containing film or a polymer mixed film in a second region different from the first region;
self-assembled the block copolymer containing film or the polymer mixed film; and
selectively removing a plurality of kinds of polymers contained in the self-assembled block copolymer containing film or polymer mixed film to leave at least one kind of polymer to thereby form a second pattern in the second region.

9. A pattern forming apparatus comprising:
a substrate-to-be-processed holding unit that fixes and holds a substrate to be processed having a film to be processed;
a material supplying unit that selectively supplies, as an application material, a block copolymer containing material containing block copolymer or a polymer mixed material containing a plurality of polymers onto the film to be processed;
a material-supply control unit that controls a supply position and a supply amount of the block copolymer containing material or the polymer mixed material supplied by the material supplying unit onto the film to be processed;
a material leveling unit that levels the block copolymer containing material or the polymer mixed material; and
a self-assembled unit that self-organizes the leveled block copolymer containing material or polymer mixed material.

10. The pattern forming apparatus according to claim 9, wherein the material-supply control unit controls the material supplying unit to identify a product region where a product is acquired on the substrate to be processed and a non-product region where a product is not acquired on the substrate to be processed and selectively supply the block copolymer containing material or the polymer mixed material to the non-product region.

11. The pattern forming apparatus according to claim 10, wherein the non-product region is a chip region present at a peripheral edge of the substrate to be processed and not functioning as a product.

12. The pattern forming apparatus according to claim 9, further comprising a substrate-to-be-processed moving unit that moves the substrate-to-be-processed moving unit to thereby two-dimensionally move the substrate to be processed in a horizontal direction.

13. The pattern forming apparatus according to claim 9, wherein the material supplying unit intermittently or continuously drops the application material onto the film to be processed.

14. The pattern forming apparatus according to claim 9, wherein the material leveling unit levels the block copolymer containing material or the polymer mixed material by pressing a flat plate against the block copolymer containing material or the polymer mixed material supplied onto the film to be processed or using a squeeze.

15. The pattern forming apparatus according to claim 9, wherein
the material leveling unit is a roller member provided above and spaced apart from the film to be processed, and
the material supplying unit supplies the block copolymer containing material or the polymer mixed material to an upper part of the rotating roller member and moves in a predetermined direction while rotating the roller member.

16. The pattern forming apparatus according to claim 9, wherein the material-supply control unit controls the supply position and the supply amount such that desired film thickness and thickness uniformity are obtained when the block copolymer containing material or the polymer mixed material supplied from the material supplying unit is leveled.

17. The pattern forming apparatus according to claim 9, wherein the self-assembled unit heats the block copolymer containing material or the polymer mixed material to thereby self-organize the block copolymer or the polymer mixed material.

18. The pattern forming apparatus according to claim 9, wherein the self-assembled unit presses the block copolymer containing material or the polymer mixed material to thereby self-organize the block copolymer or the polymer mixed material.

19. A pattern forming apparatus comprising:
a substrate-to-be-processed holding unit that fixes and holds a substrate to be processed having a film to be processed;
a material supplying unit that selectively supplies an imprint material, and a block copolymer containing material or a polymer mixed material respectively to different regions on the film to be processed;
a material-supply control unit that controls a supply position and a supply amount of the block copolymer containing material or the polymer mixed material, and the imprint material supplied by the material supplying unit;
a material leveling unit that levels the block copolymer containing material or the polymer mixed material;
a self-assembled unit that self-organizes the leveled block copolymer containing material or polymer mixed material;
a template having a molding pattern for forming a pattern on the imprint material supplied onto the film to be processed;
a template compression-bonding unit that brings the molding pattern into contact with the imprint material and compression-bonds the template to the imprint material; and
an imprint-material curing unit that cures the imprint material in a state in which the template is compression-bonded to the imprint material.
